(19) United States
(12) Patent Application Publication
(10) Pub. No.: US 2026/0287637 A1
(43) Pub. Date: Sep. 24, 2026

(54) DRIVE CIRCUIT

(71) Applicants: Mitsubishi Electric Corporation, Tokyo (JP); TMEIC Corporation, Tokyo (JP)

(72) Inventors: Seiya YOSHIDA, Chiyoda-ku, Tokyo (JP); Takeshi HORIGUCHI, Chiyoda-ku, Tokyo (JP); Yohei MITSUI, Chiyoda-ku, Tokyo (JP); Kenji ODA, Chuo-ku, Tokyo (JP); Hiroyoshi KOMATSU, Chuo-ku, Tokyo (JP)

(73) Assignees: Mitsubishi Electric Corporation, Tokyo (JP); TMEIC Corporation, Tokyo (JP)

(21) Appl. No.: 19/472,762

(22) PCT Filed: Apr. 13, 2023
(86) PCT No.: PCT/JP2023/015069

§ 371 Date: Oct. 6, 2025

(51) Int. Cl. G01R 31/26; G01R 31/52; H03K 17/56

(52) U.S. Cl. CPC G01R 31/2607; G01R 31/52; H03K 17/56

(57) ABSTRACT

In a drive circuit, a common board generates a common drive signal for controlling the on and off of a plurality of power semiconductor elements connected in parallel. Each of the individual boards is provided individually for a corresponding power semiconductor element and supplies the drive signal to the corresponding power semiconductor element. Among the individual boards, one individual board or each of some individual boards includes a detection circuit. When detecting an abnormality in electrical characteristics of the corresponding power semiconductor element, the detection circuit changes the drive signal by transmitting an abnormality detection signal to the individual boards and the common board.

### TECHNICAL FIELD

The present disclosure relates to a drive circuit, and more particularly to a drive circuit for driving a plurality of power semiconductor elements connected in parallel.

### BACKGROUND ART

In power conversion devices using power semiconductor elements such as insulated gate bipolar transistors (IGBTs) and metal-oxide-semiconductor field-effect transistors (MOSFETs), a large capacity model is configured such that a plurality of power semiconductor elements are connected in parallel to ensure a desired power capacity.

However, in the above configuration, if an overcurrent state or a short-circuit state occurs, current concentrates in any power semiconductor element among a plurality of power semiconductor elements connected in parallel, which may lead to thermal destruction of the element. Therefore, in a drive circuit that drives a plurality of power semiconductor elements connected in parallel, there is a need for a function that detects an overcurrent state or a short-circuit state of power semiconductor elements and protects the power semiconductor elements from thermal destruction.

As a drive circuit having such a short-circuit protection function, for example, drive circuits disclosed in Japanese Patent Laying-Open No. 2021-044963 (PTL 1) and Japanese Patent Laying-Open No. 2000-217337 (PTL 2) are known.

For example, “a gate drive device for driving a plurality of insulated gate semiconductor elements connected in parallel” disclosed in Japanese Patent Laying-Open No. 2021-044963 (PTL 1) includes “a gate drive circuit for driving gates of the insulated gate semiconductor elements in accordance with an externally applied control signal; an abnormality detection circuit including a plurality of abnormality detection terminals respectively corresponding to the insulated gate semiconductor elements, the abnormality detection circuit detecting an abnormal state of the insulated gate semiconductor elements and outputting an abnormality detection signal; and an output circuit connected to at least one of the abnormality detection terminals to output the abnormality detection signal to outside” (see claim 1 of PTL 1).

In the semiconductor device disclosed in Japanese Patent Laying-Open No. 2000-217337 (PTL 2) “a plurality of voltage-driven elements are divided into a plurality of groups each including parallel connection of a plurality of voltage-driven elements including a voltage-driven element having an auxiliary emitter for current detection, and each of the groups is protected from overcurrent by one overcurrent protection circuit”. Then “the auxiliary emitter, the main emitter and the gate of a voltage-driven element with largest collector current at the same gate-emitter voltage in each of the groups are connected to the overcurrent protection circuit” (see claims 1 and 2 of PTL 2).

### CITATION LIST

### Patent Literature

PTL 1: Japanese Patent Laying-Open No. 2021-044963
PTL 2: Japanese Patent Laying-Open No. 2000-217337

### SUMMARY OF INVENTION

### Technical Problem

In the drive circuit disclosed in Japanese Patent Laying-Open No. 2021-044963 (PTL 1), an abnormality detection terminal is provided corresponding to each of a plurality of semiconductor elements connected in parallel, and current flowing through a detection resistor connected to a sense emitter of each semiconductor clement is detected. In such a configuration that detects abnormality of all semiconductor elements, the abnormality detection circuit tends to be large and complex.

In the semiconductor device disclosed in Japanese Patent Laying-Open No. 2000-217337 (PTL 2), current flowing through a detection resistor connected to the auxiliary emitter of the semiconductor element that “has the largest collector current at the same gate-emitter voltage in each group” is detected. However, since the collector current is usually designed to be equal, it is impractical to identify the semiconductor element with the largest collector current at the design stage and to connect its auxiliary emitter, main emitter and gate to the overcurrent protection circuit.

The present disclosure is made in view of the above background art. An object of the present disclosure is to provide a drive circuit having a short-circuit protection function that detects a short-circuit state occurring in any of a plurality of power semiconductor elements connected in parallel with a simple configuration and protects these power semiconductor elements.

### Solution to Problem

In one aspect, a drive circuit for driving a plurality of power semiconductor elements connected in parallel with each other includes a common board and a plurality of individual boards. The common board generates a common drive signal for controlling on and off of all the power semiconductor elements connected in parallel. Each of the individual boards is provided individually for a corresponding power semiconductor element among the power semiconductor elements, and supplies the drive signal to the corresponding power semiconductor element. Among the individual boards, one individual board or each of some individual boards includes a detection circuit. When detecting an abnormality in electrical characteristics of the corresponding power semiconductor element, the detection circuit changes the drive signal by transmitting an abnormality detection signal to the individual boards and the common board, or transmitting the abnormality detection signal to the common board without transmitting the abnormality detection signal to the individual boards.

### Advantageous Effects of Invention

According to the above aspect, a detection circuit for abnormality detection is provided in one individual board or each of some individual boards among a plurality of individual boards, so that a short-circuit state that occurs in any of a plurality of power semiconductor elements connected in parallel can be detected with a simple configuration, and these power semiconductor elements can be protected.

### BRIEF DESCRIPTION OF DRAWINGS

FIG. 1 is a diagram showing a configuration example of a drive circuit according to a first embodiment.

FIG. 2A is a circuit diagram showing an example of a logical operation circuit 14, a detection circuit 41, and a switching circuit 11 in FIG. 1.

FIG. 2B shows a truth table of an SRFF circuit 18 in FIG. 2A.

FIG. 3 is a diagram showing another example of the configuration of a drive circuit according to the first embodiment.

FIG. 4 is a circuit diagram showing a configuration example of a soft shutdown circuit 15 in FIG. 1.

FIG. 5 is a diagram showing a configuration example of a drive circuit according to a modification of the first embodiment.

FIG. 6 is a diagram showing a configuration example of a drive circuit according to a second embodiment.

FIG. 7 is a diagram showing an example of IGBT gate charge characteristic.

FIG. 8 is a diagram showing a configuration example of a drive circuit according to a modification of the second embodiment.

FIG. 9 is a diagram showing a configuration example of a drive circuit according to a third embodiment.

FIG. 10 is a diagram showing a configuration example of a drive circuit according to a modification of the third embodiment.

FIG. 11A is a diagram for explaining the reason why current and voltage of each IGBT vary in a plurality of IGBTs connected in parallel.

FIG. 11B is a diagram for explaining the reason why the on-resistance of each IGBT varies in a plurality of IGBTs connected in parallel.

FIG. 12 is a diagram showing a configuration example of a main circuit for one phase of a power conversion device.

FIG. 13 is a diagram showing another configuration example of a main circuit for one phase of a power conversion device.

FIG. 14A is a diagram showing an example of a drive circuit that drives an upper arm of the main circuit shown in FIG. 13.

FIG. 14B is a diagram showing another example of the drive circuit that drives an upper arm of the main circuit shown in FIG. 13.

FIG. 14C is a diagram showing an example of the drive circuit that drives an upper arm of the main circuit in another configuration example.

FIG. 14D is a diagram showing another example of the drive circuit that drives an upper arm of the main circuit shown in FIG. 14C.

FIG. 15 is a diagram showing a configuration example of a drive circuit according to a fifth embodiment.

FIG. 16 is a diagram showing a configuration example of a drive circuit according to a modification of the fifth embodiment.

### DESCRIPTION OF EMBODIMENTS

Embodiments will be described in detail below with reference to the drawings. The same or corresponding parts are denoted by the same reference signs and a description thereof is not repeated.

### First Embodiment

### [Overall Configuration of Main Circuit and Drive Circuit]

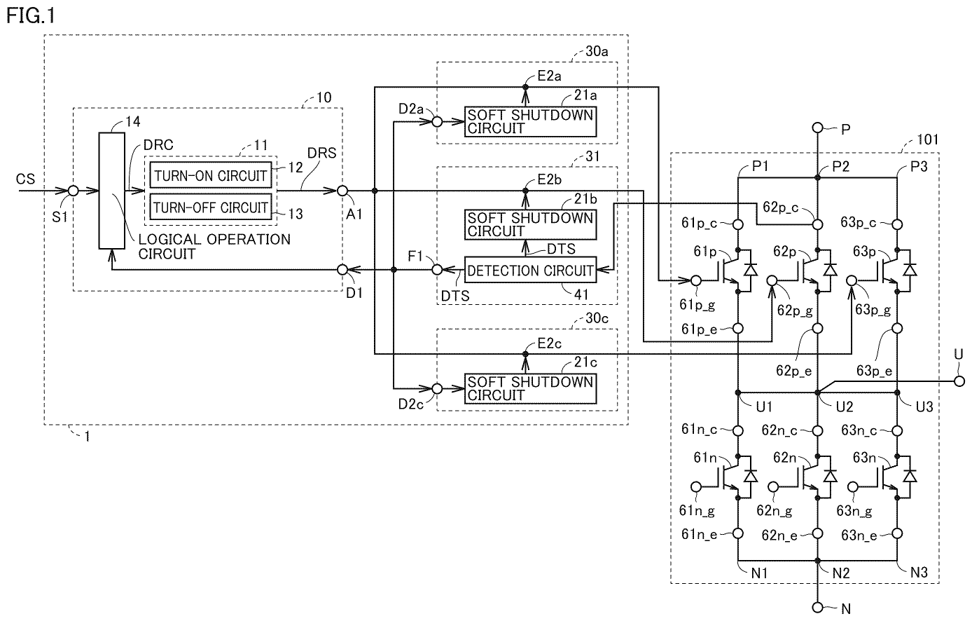

FIG. 1 is a diagram showing a configuration example of a drive circuit according to a first embodiment. A drive circuit 1 in FIG. 1 drives a plurality of power semiconductor elements connected in parallel. Furthermore, drive circuit 1 has a function to detect an abnormal state (that is, an overcurrent state or a short-circuit state) of a power semiconductor element to protect a plurality of power semiconductor elements from an abnormal state.

FIG. 1 shows a U-phase that constitutes a main circuit 101 of a power conversion device by way of example. Drive circuit 1 drives a plurality of power semiconductor elements connected in parallel that constitute an upper arm of the U. phase. The power conversion device may be an inverter for converting DC power into AC power or a converter for converting AC power into DC power.

In FIG. 1, three IGBTs 61p, 62p, and 63p are illustrated as a plurality of power semiconductor elements. The number and type of power semiconductor elements are not limited to these. For example, the number of power semiconductor elements may be two or four or more, and the type of power semiconductor elements may be power MOSFET or bipolar power transistor.

A plurality of power semiconductor elements connected in parallel with each other may be provided on a single main circuit board or on a plurality of main circuit boards. A plurality of power semiconductor elements may be arranged in a row or multiple rows on each main circuit board.

Drive circuit 1 includes a common board 10 and individual boards 30a, 31, and 30c. Common board 10 generates a common drive signal DRS for controlling the on and off of IGBTs 61p, 62p, and 63p connected in parallel. Individual boards 30a, 31, and 30c correspond individually to IGBTs 61p, 62p, and 63p, respectively, and supply the generated drive signal DRS to the corresponding IGBTs.

More specifically, common board 10 includes a control signal input terminal S1, a drive signal output terminal A1, a detection signal input terminal D1, a switching circuit 11, and a logical operation circuit 14. Switching circuit 11 includes a turn-on circuit 12 and a turn-off circuit 13 inside.

Individual board 30a includes a detection signal input terminal D2a and a soft shutdown circuit 21a. Similarly, individual board 30c includes a detection signal input terminal D2c and a soft shutdown circuit 21c. Individual board 31 includes a detection signal output terminal F1, a soft shutdown circuit 21b, and a detection circuit 41, The connections and functions of the components of common board 10 and individual boards 30a, 31, and 30c described above will be explained in conjunction with the explanation of the operation of drive circuit 1.

Main circuit 101 includes U, V, and W phases connected in parallel with each other between a positive terminal P and a negative terminal N. Although only the U-phase configuration is shown in FIG. 1, the configurations of the V-phase and the W-phase are the same.

The U-phase of main circuit 101 includes an upper arm configured with IGBTs 61p, 62p, and 63p connected in parallel and a lower arm configured with IGBTs 61n, 62n, and 63n connected in parallel.

IGBT 61p and IGBT 61n are connected in series between a positive node P1 and a negative node NI via a connection node U1. IGBT 62p and IGBT 62n are connected in series between a positive node P2 and a negative node N2 via a connection node U2. IGBT 63p and IGBT 63n are connected in series between a positive node P3 and a negative node N3 via a connection node U3. Positive node P2 is connected to each of positive nodes P1 and P3 and further connected to positive terminal P. Negative node N2 is connected to each of negative nodes N1 and N3 and further connected to negative terminal N. Connection node U2 is connected to each of connection nodes U1 and U3 and further connected to a U-phase load terminal U.

Therefore, collector terminals 61p_c, 62p_c, and 63p_c of IGBTs 61p, 62p, and 63p that constitute the upper arm are connected to positive terminal P via the common positive node P2. Emitter terminals 61_n_e, 62n_e, and 63n_e of IGBTs 61n, 62n, and 63n that constitute the lower arm are connected to negative terminal N via the common negative node N2. Emitter terminal 61p_e of IGBT 61p is connected to collector terminal 61n_c of IGBT 61n via connection node U1. Emitter terminal 62p_e of IGBT 62p is connected to collector terminal 62n_c of IGBT 62n via connection node U2. Emitter terminal 63p_e of IGBT 63p is connected to collector terminal 63n_c of IGBT 63n via connection node U3.

Gate terminal 61p_g of IGBT 61p that constitutes the upper arm is connected to drive signal output terminal A1 of common board 10 via the corresponding individual board 30a. Similarly, gate terminal 62p_g of IGBT 62p that constitutes the upper arm is connected to drive signal output terminal A1 of common board 10 via the corresponding individual board 31. Similarly, gate terminal 63p_g of IGBT 63p that constitutes the upper arm is connected to drive signal output terminal A1 of common board 10 via the corresponding individual board 30c.

Collector terminal 62p_c of IGBT 62p that constitutes the upper arm is connected to detection circuit 41 provided on the corresponding individual board 31 to detect a collector potential. Although not shown in FIG. 1, emitter terminal 62p_e of IGBT 62p that constitutes the upper arm is also connected to detection circuit 41 provided on individual board 31 to detect an emitter potential.

The respective gate terminals 61n_g, 62n_g, and 63n_g of IGBTs 61n, 62n, and 63n that constitute the lower arm are connected to a not-shown drive circuit for the lower arm.

### [Operation of Drive Circuit]

The operation of drive circuit 1 in FIG. 1 will now be described. As shown in FIG. 1, a control signal CS is input from outside drive circuit 1 to control signal input terminal S1 of common board 10. Furthermore, a detection signal DTS generated by detection circuit 41 of individual board 31 is input to detection signal input terminal D1 of common board 10. Common board 10 generates a drive signal DRS for driving IGBTs 61p, 62p and 63p, based on these control signal CS and detection signal DTS, and outputs the generated drive signal DRS from drive signal output terminal A1.

More specifically, logical operation circuit 14 provided on common board 10 generates a drive command DRC by performing logic operations using control signal CS input to control signal input terminal S1 and detection signal DTS input to detection signal input terminal D1. Logical operation circuit 14 outputs drive command DRC to switching circuit 11 provided on common board 10.

For example, when control signal CS input to control signal input terminal S1 is at H (high) level and detection signal DTS input to detection signal input terminal D1 is at L (low) level, logical operation circuit 14 outputs drive command DRC at H level to switching circuit 11. When control signal CS input to control signal input terminal S1 is at H level and detection signal DTS input to detection signal input terminal D1 is at H level, logical operation circuit 14 outputs drive command DRC at L level to switching circuit 11. In other words, when detection signal DTS is at L level indicating a normal state, logical operation circuit 14 outputs drive command DRC having a logic level corresponding to the logic level of control signal CS. When detection signal DTS is at H level indicating an abnormal state, logical operation circuit 14 outputs drive command DRC at L level regardless of the logic level of control signal CS. In the following description, H level is also denoted as Hi and L level is also denoted as Lo.

Switching circuit 11 generates drive signal DRS by operating turn-on circuit 12 and turn-off circuit 13 complementarily in accordance with the logic level of drive command DRC input from logical operation circuit 14. Specifically in FIG. 1, when drive command DRC is at H level, a switching element 19a of turn-on circuit 12 turns on, so that switching circuit 11 outputs drive signal DRS at H level. When drive command DRC is at L level, a switching element 19b of turn-off circuit 13 turns on, so that switching circuit 11 outputs drive signal DRS at L level.

Drive signal DRS output from switching circuit 11 is input to the respective gate terminals 61p_g, 62p_g, and 63p_g of IGBTs 61p, 62p, and 63p via individual boards 30a, 31, and 30c corresponding to IGBTs 61p, 62p, and 63p, respectively. When drive signal DRS is at H level, IGBTs 61p, 62p, and 63p are in the ON state, and when drive signal DRS is at L level, IGBTs 61p, 62p, and 63p are in the OFF state.

Detection circuit 41 provided on individual board 31 detects an abnormal state of IGBT 62p based on the physical quantity (that is, electrical characteristics) acquired for IGBT 62p which is one of three IGBTs 61p, 62p, and 63p. When an abnormal state of IGBT 62p is detected, detection circuit 41 outputs detection signal DTS (hereinafter referred to as an abnormality detection signal) indicating an abnormal state to soft shutdown circuit 21b provided on individual board 31, and also outputs detection signal DTS indicating an abnormal state to the outside of individual board 31 via detection signal output terminal F1. Detection signal DTS output via detection signal output terminal F1 is input to logical operation circuit 14 via detection signal input terminal D1 of common board 10. Furthermore, detection signal DTS is input to soft shutdown circuit 21a via detection signal input terminal D2a of individual board 30a and input to soft shutdown circuit 21c via detection signal input terminal D2c of individual board 30c. The detailed operation of detection circuit 41 will be described later.

Soft shutdown circuit 21a provided on individual board 30a is connected to wiring for the drive signal (more specifically, node E2a of individual board 30a) that connects drive signal output terminal A1 of common board 10 to gate terminal 61p_g of IGBT 61p. When abnormality detection signal DTS is input from detection circuit 41, soft shutdown circuit 21a lowers a potential of node E2a on the wiring and clamps a gate-emitter voltage to a predetermined voltage. This can temporarily lower short-circuit current and lower a current change rate in turn-off operation by turn-off circuit 13. This can suppress a surge voltage produced during the turn-off operation of turn-off circuit 13.

Similarly, soft shutdown circuit 21b provided on individual board 31 is connected to wiring for drive signal DRS (more specifically, node E2b of individual board 31) that connects drive signal output terminal A1 of common board 10 to gate terminal 62p_g of IGBT 62p. When abnormality detection signal DTS is input from detection circuit 41, soft shutdown circuit 21b lowers a potential of node E2b on the wiring and clamps a gate-emitter voltage to a predetermined voltage. This can temporarily lower short-circuit current and lower a current change rate in turn-off operation by turn-off circuit 13. This can suppress a surge voltage produced during the turn-off operation of turn-off circuit 13.

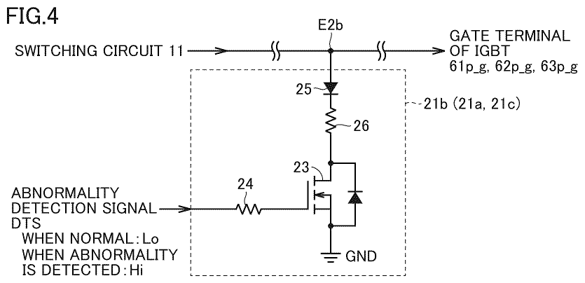

Similarly, soft shutdown circuit 21c provided on individual board 30c is connected to wiring for the drive signal (more specifically, node E2c of individual board 30c) that connects drive signal output terminal A1 of common board 10 to gate terminal 63p_g of IGBT 63p. When abnormality detection signal DTS is input from detection circuit 41, soft shutdown circuit 21c lowers a potential of node E2c on the wiring and clamps a gate-emitter voltage to a predetermined voltage. This can temporarily lower short-circuit current and lower a current change rate in turn-off operation by turn-off circuit 13. This can suppress a surge voltage produced during the turn-off operation of turn-off circuit 13. A specific circuit configuration example of soft shutdown circuits 21a, 21b, and 21c will be described later with reference to FIG. 4.

### [Detailed Operation of Detection Circuit]

The operation of detection circuit 41 in FIG. 1 will be described in more detail below. In the first embodiment, detection circuit 41 determines an abnormality based on the collector-emitter voltage of the corresponding IGBT 62p.

Three IGBTs 61p, 62p, and 63p connected in parallel are connected with the collector-emitter in common, and if the individual differences in the IGBTs and the parasitic impedance of the wiring can be ignored, the respective voltages of IGBTs 61p, 62p, and 63p connected in parallel are equal. The respective currents flowing through IGBTs 61p, 62p, and 63p are also equal.

Detection circuit 41 provided on individual board 31 detects an abnormality based on the collector-emitter voltage of the corresponding IGBT 62p. When IGBT 62p turns on and causes a short-circuit state and a high short-circuit current flows through IGBT 62p, the collector-emitter voltage of IGBT 62p becomes higher than the ON-state voltage in normal operation. Therefore, an abnormality can be detected by setting an appropriate threshold value for the collector-emitter voltage.

When the upper and lower arms of the same phase that constitutes main circuit 101 enter the ON state simultaneously, main circuit 101 is short-circuited. Therefore, the upper and lower arms of the same phase alternately turn on in normal operation of main circuit 101. However, due to a fault or a false turn-on of IGBTs, the upper and lower arms of the same phase may enter the ON state simultaneously. This is called an arm short circuit.

An arm short circuit occurs when an ON command is input to the IGBTs connected in parallel in the upper arm if any one of the IGBTs that constitute the lower arm is in a conducting state due to a short circuit fault or a false ON signal input. In drive circuit 1 of the first embodiment shown in FIG. 1, when an arm short circuit occurs, detection circuit 41 provided on individual board 31 corresponding to IGBT 62p in the upper arm detects the arm short circuit.

Specifically, suppose that an ON command is input to all IGBTs in the upper arm when IGBT 61n which is one of the IGBTs in the lower arm is in a conducting state. In this case, there are three paths for the short-circuit current to flow, namely, a path through IGBT 61p and IGBT 61n, a path through IGBT 62p and IGBT 61n, and a path through IGBT 63p and IGBT 61n.

In other words, the short-circuit current flowing from positive terminal P to negative terminal N is split at positive node P2 of the upper arm and flows through all IGBTs 61p, 62p, and 63p in the upper arm. If the individual differences in the IGBTs and the parasitic impedance of the wiring can be ignored, the short-circuit current flows equally through three IGBTs 61p, 62p, and 63p. In this case, the collector-emitter voltages of IGBTs 61p, 62p, and 63p in the upper arm are of the same magnitude and higher than the ON-state voltage in normal operation. Thus, detection circuits 41 as many as IGBTs connected in parallel are not necessary to detect an arm short circuit, and a single detection circuit 41, which is less than the number of IGBTs in parallel, can detect an arm short circuit.

In the above explanation, a case where IGBT 61n is short-circuited has been discussed. However, this is applicable to a case where IGBT 62n or IGBT 63n is short-circuited. In other words, whichever IGBT in the lower arm is short-circuited, the short-circuit current flows equally through the three IGBTs in the upper arm if the individual differences in the IGBTs and the parasitic impedance of the wiring can be ignored. In any case, an arm short circuit can be detected by a single detection circuit 41, which is less than the number of IGBTs in parallel.

In addition to an arm short circuit, there are other short-circuit states, such as a load short circuit in which a load such as a motor has a short-circuit state. There are two cases: a case where a load is short-circuited when the upper arm is in the ON state; and a case where a load is short-circuited when the lower arm is in the ON state. Detection circuit 41 provided in drive circuit 1 in FIG. 1 is connected to the upper arm and thus can detect a load short circuit when the upper arm is in the ON state.

Specifically, if a load short circuit occurs when the upper arm is in the ON state, a short-circuit current flows from positive terminal P to U-phase load terminal U. The short-circuit current is split at positive node P2 of the upper arm and flows through all IGBTs 61p, 62p, and 63p in the upper arm. If the individual differences in the IGBTs and the parasitic impedance of the wiring can be ignored, the short-circuit current flows equally through three IGBTs 61p, 62p, and 63p. In this case, the collector-emitter voltages of IGBTs 61p, 62p, and 63p in the upper arm are of the same magnitude and higher than the ON-state voltage in normal operation. Thus, detection circuits 41 as many as IGBTs connected in parallel are not necessary to detect a load short circuit, and a single detection circuit 41, which is less than the number of IGBTs in parallel, can detect a load short circuit.

### [Configuration Example and Operation of Detection Circuit 41, Logical Operation Circuit, and Switching Circuit]

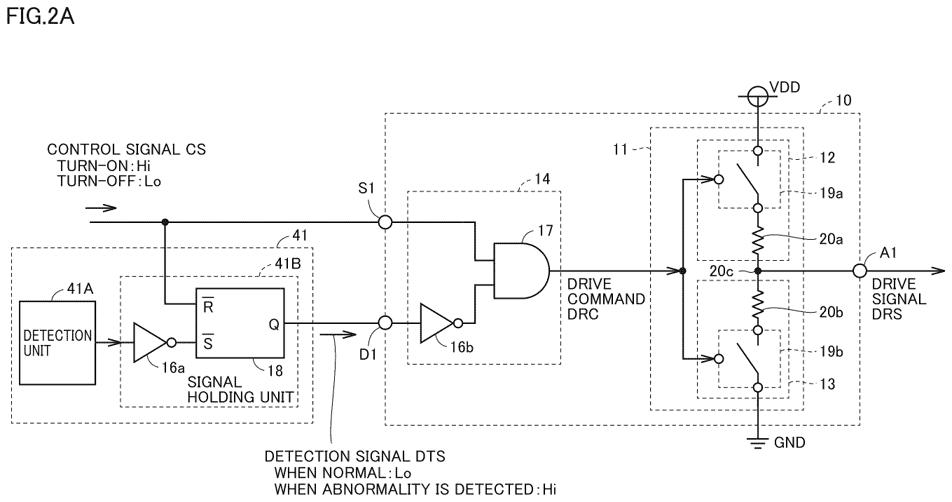

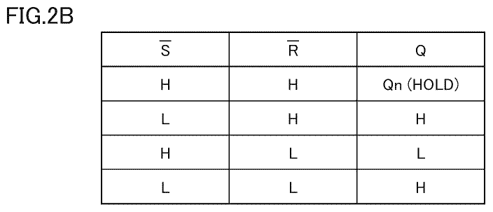

Referring to FIG. 2A and FIG. 2B, a configuration example and operation of detection circuit 41, logical operation circuit 14, and switching circuit 11 will now be described.

FIG. 2A is a circuit diagram showing an example of detection circuit 41, logical operation circuit 14, and switching circuit 11 in FIG. 1, Detection circuit 41 includes a detection unit 41A and a signal holding unit 41B.

Signal holding unit 41B in FIG. 2A includes a NOT circuit 16a and a set-reset flip-flop (SRFF) circuit 18. SRFF circuit 18 includes an inverting set terminal (/S terminal), an inverting reset terminal (/R terminal), and an output terminal (Q terminal). In the present description, the symbol “/” means inversion. Logical operation circuit 14 includes a NOT circuit 16b and an AND circuit 17.

Control signal input terminal S1 is connected to the/R terminal of SRFF circuit 18 and connected to a first input node of AND circuit 17. Input terminal D1 is connected to the/S terminal of SRFF circuit 18 via NOT circuit 16a. The Q terminal of SRFF circuit 18 is connected to a second input node of AND circuit 17 via NOT circuit 16b. Drive command DRC is output to switching circuit 11 from an output node of AND circuit 17.

Switching circuit 11 includes turn-on circuit 12 and turn-off circuit 13. Turn-on circuit 12 includes a switching element 19a and a common gate resistor 20a connected in series with each other between a high potential-side power supply node VDD and an output node 20c. Turn-off circuit 13 includes a switching element 19b and a common gate resistor 20b connected in series with each other between a low potential-side ground GND and output node 20c. Output node 20c corresponds to the connection point of common gate resistors 20a and 20b. Switching elements 19a and 19b are, for example, MOSFETs, bipolar transistors, or the like. Switching elements 19a and 19b complementarily turn on and off in accordance with drive command DRC.

The operation of logical operation circuit 14 will now be described.

Logical operation circuit 14 receives control signal CS via control signal input terminal S1 and receives detection signal DTS via detection signal input terminal D1. In the present embodiment, control signal CS is at H level (Hi) when the IGBTs are set to the ON state and at L level (Lo) when the IGBTs are set to the OFF state. In the present embodiment, detection signal DTS is at L level (Lo) when main circuit 101 is normal, and at H level (Hi) when an abnormality of main circuit 101 such as overcurrent and short-circuit current is detected.

FIG. 2B shows a truth table of SRFF circuit 18 in FIG. 2A. Before the start of operation, a L-level signal is output as control signal CS to set all IGBTs to the OFF state, so a L-level signal is input to the/R terminal. A H-level signal is thereafter input as control signal CS to the/R terminal. In this state, when a L-level signal is input to the/S terminal, an output signal from the Q terminal goes to H level. On the other hand, when a H-level signal is input to the/S terminal, an output signal from the Q terminal goes to L level. When a L-level signal is input to the/S terminal, an output signal from the Q terminal is at H level regardless of the input signal to the/R terminal. In other words, when detection unit 41A detects an abnormality, the signal output from/Q holds H level (abnormal state) until detection unit 41A detects normality and the control signal of a L-level signal is output.

Returning to FIG. 2A, first, the operation of signal holding unit 41B and logical operation circuit 14 when main circuit 101 is normal will be described. Before the start of operation, since a L-level signal, which is a normal signal, is input to detection signal input terminal D1, a H-level signal, which is an inverted signal, is input to the/S terminal of SRFF circuit 18 via NOT circuit 16a. In order to set all IGBTs to the OFF state, a L-level signal is output as control signal CS, and a L-level signal is input to the /R terminal. Thus, a L-level signal is output from the Q terminal of SRFF circuit 18. The L-level signal output from the Q terminal of SRFF circuit 18 is inverted by NOT circuit 16b and input as a H-level signal to AND circuit 17. AND circuit 17 outputs the logical product of this H-level signal and control signal CS as drive command DRC to switching circuit 11. Therefore, a L-level signal is output as drive command DRC output from AND circuit 17. Next, a turn-on command is output. In other words, when a H-level signal is input to the/R terminal, an output signal output from the Q terminal goes to L level because a H-level signal is input to the/S terminal, and drive command DRC output from AND circuit 17 goes to H level.

Next, the operation of signal holding unit 41B and logical operation circuit 14 when main circuit 101 is abnormal will be described. In this case, in a state in which a H-level signal is input to the/R terminal and a H-level signal is input to the/S terminal, H level is input to detection signal input terminal D1. Thus, a L-level signal, which is an inverted signal, is input to the/S terminal of SRFF circuit 18 via NOT circuit 16a. As a result, a H-level signal is output from the Q terminal. The H-level signal output from the Q terminal is inverted by NOT circuit 16b and input as a L-level signal to AND circuit 17. AND circuit 17 outputs the logical product of this L-level signal and control signal CS. Therefore, drive command DRC output from AND circuit 17 goes to L level, and this drive command DRC at L level is input to switching circuit 11.

In this way, when an abnormality of main circuit 101 is detected by detection circuit 41, detection signal DTS at H level is input to detection signal input terminal D1, and drive command DRC input to switching circuit 11 goes to L level. As a result, switching circuit 11 performs turn-off operation.

The operation of switching circuit 11 will now be described. Switching circuit 11 receives drive command DRC output from logical operation circuit 14. Based on drive command DRC input to switching circuit 11, turn-on circuit 12 and turn-off circuit 13 operate complementarily to output drive signal DRS to IGBTs 61p, 62p, and 63p. When an ON command (drive command DRC at H level) is input, switching element 19a of turn-on circuit 12 turns on to set IGBTs 61p, 62p, and 63p to the ON state. When an OFF command (drive command DRC at L level) is input, switching element 19b of turn-off circuit 13 turns on to set IGBTs 61p, 62p, and 63p to the OFF state.

The operation of logical operation circuit 14 and switching circuit 11 described above can be summarized as follows. When abnormality detection signal DTS is input via detection signal input terminal D1 of common board 10, logical operation circuit 14 sets drive command DRC input to switching circuit 11 to an OFF command (L level in the present embodiment) and holds this state. If IGBTs 61p, 62p, and 63p are in the ON state, switching circuit 11 receiving the OFF command sets the OFF state and then holds the OFF state. If IGBTs 61p, 62p, and 63p are in the OFF state, switching circuit 11 receiving the OFF command holds the OFF state as it is.

On the other hand, when detection signal DTS input via detection signal input terminal D1 of common board 10 indicates a normal state, logical operation circuit 14 switches drive command DRC to an ON command and an OFF command in accordance with the logic level of control signal CS. As a result, switching circuit 11 switches IGBTs 61p, 62p, and 63p to the ON state and the OFF state in accordance with the ON command and the OFF command of drive command DRC, respectively.

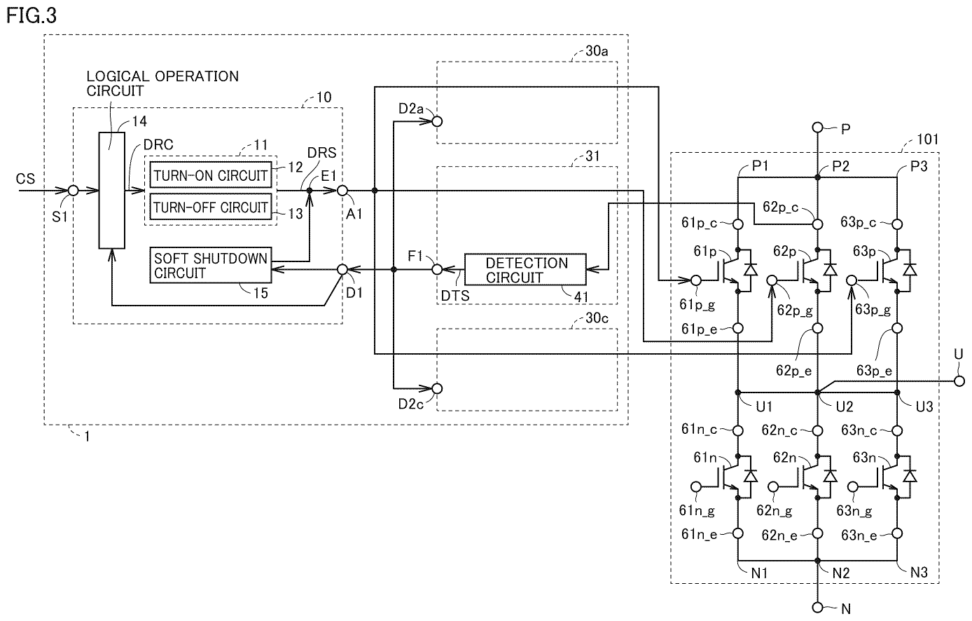

FIG. 3 is a diagram showing another example of the configuration example of the drive circuit according to the first embodiment. In FIG. 1, individual board 30a includes soft shutdown circuit 21a, individual board 30c includes soft shutdown circuit 21c, and individual board 31 includes soft shutdown circuit 21b and detection circuit 41, but in FIG. 3, common board 10 includes a soft shutdown circuit 15.

Soft shutdown circuit 15 provided on common board 10 is connected to wiring for the drive signal (more specifically, node El of the wiring) that connects switching circuit 11 of common board 10 to drive signal output terminal A1. When abnormality detection signal DTS indicating that main circuit 101 is in an abnormal state is input from detection circuit 41, soft shutdown circuit 15 lowers a potential of node El on the wiring and clamps a gate-emitter voltage to a predetermined voltage. This can temporarily lower short-circuit current and lower a current change rate in turn-off operation by turn-off circuit 13. This can suppress a surge voltage produced during the turn-off operation of turn-off circuit 13.

### [Configuration Example and Operation of Soft Shutdown Circuit]

FIG. 4 is a circuit diagram showing a configuration example of soft shutdown circuit 21b in FIG. 1. Referring to FIG. 4, a configuration example and operation of soft shutdown circuit 21b will now be described. The configurations and operation of soft shutdown circuits 15, 21a, and 21c are the same.

Soft shutdown circuit 21b in FIG. 4 includes an N-channel MOSFET 23, resistor elements 24 and 26, and a diode 25. The drain of MOSFET 23 is connected to a connection node E2b via diode 25 and resistor element 26 for soft shutdown connected in series. The direction from connection node E2b to the drain of MOSFET 23 is the forward direction of diode 25. The source of MOSFET 23 is connected to ground GND of drive circuit 1. The gate of MOSFET 23 is connected to detection signal input terminal D1 via resistor element 24 for driving MOSFET.

Referring now to FIG. 2A and FIG. 4, the operation of soft shutdown circuit 21b will be described. In normal operation in which no abnormality of main circuit 101 is detected by detection circuit 41, detection signal DTS at L level is input to the gate of MOSFET 23 via detection signal input terminal D1. Therefore, MOSFET 23 is in the OFF state. In this case, at a time of turn-off of IGBTs 61p, 62p, and 63p when an OFF command is output as drive command DRC from logical operation circuit 14, the charge in the gates of IGBTs 61p, 62p, and 63p is removed via common gate resistor 20b of turn-off circuit 13, whereby IGBTs 61p, 62p, 63p turn off.

On the other hand, in the ON state of IGBTs 61p, 62p, and 63p, when abnormality detection signal DTS at H level is input to the gate of MOSFET 23 from detection circuit 41, MOSFET 23 enters the ON state. As a result, output node 20c of switching circuit 11 is connected to power supply node VDD via common gate resistor 20a of turn-on circuit 12 and connected to ground GND via resistor element 26 of the soft shutdown circuit. As a result, the voltage between power supply node VDD and ground GND is divided by common gate resistor 20a and resistor element 26 for soft shutdown, and the divided voltage is applied between the gate and emitter of IGBTs 61p, 62p, and 63p, so that the gate-emitter voltages of IGBTs 61p, 62p, and 63p lowers. The short-circuit current flowing through IGBTs 61p, 62p, and 63p is then reduced due to the lowering in the gate-emitter voltage. Abnormality detection signal DTS is also input to logical operation circuit 14, but drive command DRC does not immediately switch from an ON command to an OFF command due to a time delay in logical operation circuit 14. Therefore, drive command DRC switches to an OFF command after the short-circuit current is reduced due to the lowering in the gate-emitter voltage. As a result, the charge in the gates of IGBTs 61p, 62p, and 63p is removed via common gate resistor 20b of turn-off circuit 13. As a result, a current peak value and a current change rate di/dt when IGBTs 61p, 62p, and 63p are turned off by turn-off circuit 13 can be lowered, thereby suppressing a surge voltage. In other words, the soft shutdown of IGBTs 61p, 62p, and 63p is achieved.

### [Effects of First Embodiment]

As explained above, in drive circuit 1 according to the first embodiment, detection circuit 41 is provided in any one of the individual boards (individual boards 30a, 31, and 30c above) respectively corresponding to a plurality of power semiconductor switching elements (IGBTs 61p, 62p, and 63p above) connected in parallel. This detection circuit 41 can detect an abnormality in a plurality of power semiconductor switching elements connected in parallel. When an abnormality is detected in these power semiconductor switching elements, drive command DRC input from logical operation circuit 14 to switching circuit 11 is held at an OFF command. This ensures that a plurality of power semiconductor switching elements connected in parallel are turned off, and these power semiconductor switching elements can be protected.

In the event of an abnormality, a large current flows through a plurality of power semiconductor switching elements connected in parallel, and if such a large current is shut down at a shutdown speed in normal operation, a large surge voltage may occur to destroy these power semiconductor switching elements. As for the speed of the OFF operation in the event of an abnormality, the gate-emitter voltage is clamped to a predetermined voltage by the resistance of resistor element 26 for soft shutdown provided in soft shutdown circuit 15 or 21a, 21b, and 21c, thereby temporarily lowering the short-circuit current and lowering the current change rate in turn-off operation by turn-off circuit 13. In this way, the destruction of power semiconductor switching elements due to the OFF operation during abnormality detection can be prevented.

Thus, an abnormality in a plurality of power semiconductor switching elements connected in parallel can be detected and these power semiconductor switching elements can be protected with a low-cost and simple configuration.

### [Modification of First Embodiment]

In the first embodiment, IGBTs 61p, 62p, 63p are illustrated as a plurality of power semiconductor switching elements connected in parallel. However, power semiconductor switching elements are not necessarily limited to IGBTs. For example, MOSFETs may be used as power semiconductor switching elements, or other types of semiconductor switching elements may be used. The material of power semiconductor switching elements is not limited to silicon and may be a wide bandgap semiconductor (for example, silicon carbide, gallium nitride, gallium oxide, diamond, etc.).

The power semiconductor switching elements described above may be in either a discrete form or a power module form. Types of power modules include a 1-in-1 module (1-pack module) that constitutes one arm of a power conversion device, a 2-in-1 module (2-pack module) that constitutes one phase of a power conversion device, that is, two arms connected in series, and a 6-in-1 module (6-pack module) that constitutes upper and lower arms of three phases of a power conversion device. When the IGBTs connected in parallel are in the power module form, a module of any circuit configuration may be used, or a module of any other configuration may be used.

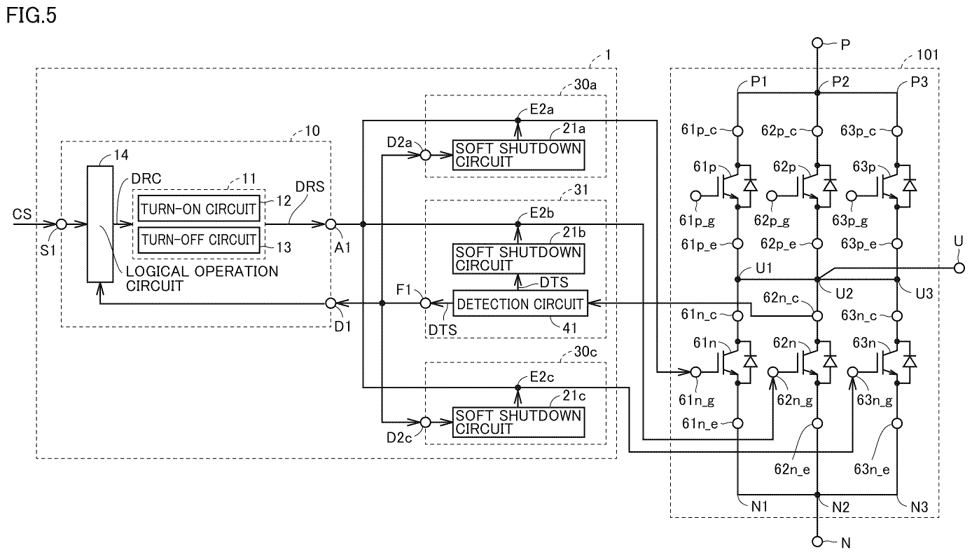

Drive circuit 1 in FIG. 1 may be configured to drive the lower arm of main circuit 101. Alternatively, a drive circuit that drives the upper arm of main circuit 101 and a drive circuit that drives the lower arm of main circuit 101 may be provided separately. Referring to FIG. 5, a case where drive circuit 1 drives the lower arm of main circuit 101 will be described below.

FIG. 5 is a diagram showing a configuration example of a drive circuit according to a modification of the first embodiment. Drive circuit 1 in FIG. 5 differs from drive circuit 1 in FIG. 1 in that it drives IGBTs 61n, 62n, and 63n that constitute the lower arm of main circuit 101, instead of IGBTs 61p, 62p, and 63p that constitute the upper arm of main circuit 101. Drive circuit 1 in FIG. 5 has a function to detect an abnormal state of IGBTs 61n, 62n, and 63n connected in parallel to protect a plurality of power semiconductor elements from an abnormal state.

More specifically, the configuration of drive circuit 1 in FIG. 5 and the configuration of main circuit 101 in FIG. 5 are the same as in FIG. 1, but the connection between them differs from that in FIG. 1. In the following, differences from the case in FIG. 1 will mainly be described, and the same or corresponding parts as in FIG. 1 are denoted by the same reference signs and will not be further elaborated.

As shown in FIG. 5, common board 10 that constitutes drive circuit 1 generates a common drive signal DRS for controlling the on and off of IGBTs 61n, 62n, and 63n connected in parallel that constitute the lower arm. Individual boards 30a, 31, and 30c that constitute drive circuit 1 correspond individually to IGBTs 61n, 62n, and 63n, respectively, and supply the generated drive signal DRS to the corresponding IGBTs.

Specifically, gate terminal 61n_g of IGBT 61n that constitutes the lower arm is connected to drive signal output terminal A1 of common board 10 via the corresponding individual board 30a. Similarly, gate terminal 62n_g of IGBT 62n that constitutes the lower arm is connected to drive signal output terminal A1 of common board 10 via the corresponding individual board 31. Similarly, gate terminal 63n_g of IGBT 63n that constitutes the lower arm is connected to drive signal output terminal A1 of common board 10 via the corresponding individual board 30c.

Collector terminal 62n_c of IGBT 62n that constitutes the lower arm is connected to detection circuit 41 provided on the corresponding individual board 31 to detect a collector potential. Although not shown in FIG. 5, emitter terminal 62n_e of IGBT 62n that constitutes the lower arm is also connected to detection circuit 41 provided on individual board 31 to detect an emitter potential.

Soft shutdown circuit 21a on individual board 30a is connected to wiring for the drive signal (more specifically, node E2a of individual board 30a) that connects drive signal output terminal A1 of common board 10 to gate terminal 61n_g of IGBT 61n. Soft shutdown circuit 21b on individual board 31 is connected to wiring for drive signal DRS (more specifically, node E2b of individual board 31) that connects drive signal output terminal A1 of common board 10 to gate terminal 62n_g of IGBT 62n. Soft shutdown circuit 21c on individual board 30c is connected to wiring for the drive signal (more specifically, node E2c of individual board 30c) that connects drive signal output terminal A1 of common board 10 to gate terminal 63n_g of IGBT 63n.

When abnormality detection signal DTS is input from detection circuit 41, soft shutdown circuits 21a to 21c respectively lower potentials of nodes E2a to E2c and clamp gate-emitter voltages to a predetermined voltage, in the same manner as in FIG. 1. This can temporarily lower short-circuit current and lower a current change rate in turn-off operation by turn-off circuit 13. This can suppress a surge voltage produced during the turn-off operation of turn-off circuit 13.

The respective gate terminals 61p_g, 62p_g, and 63p_g of IGBTs 61p, 62p, and 63p that constitute the upper arm are connected to a not-shown drive circuit for the upper arm.

The operation of detection circuit 41 in drive circuit 1 in FIG. 5 will be described below. Detection circuit 41 determines an abnormality in main circuit 101 based on the collector-emitter voltage of IGBT 62n.

Three IGBTs 61n, 62n, and 63n connected in parallel are connected with the collector-emitter in common, and if the individual differences in the IGBTs and the parasitic impedance of the wiring can be ignored, the respective voltages of IGBTs 61n, 62n, and 63n connected in parallel are equal. Similarly, the respective currents flowing through IGBTs 61n, 62n, and 63n are also equal.

Detection circuit 41 provided on individual board 31 detects an abnormality based on the collector-emitter voltage of the corresponding IGBT 62n. When a high short-circuit current flows through IGBT 62n in the event of a short circuit, the collector-emitter voltage of IGBT 62n becomes higher than the ON-state voltage in normal operation. Therefore, an abnormality can be detected by setting an appropriate threshold value for the collector-emitter voltage.

The operation of detection circuit 41 in drive circuit 1 in FIG. 5 in a case of arm short circuit and in a case of load short circuit will be described specifically below.

An arm short circuit occurs when an ON command is input to the IGBTs connected in parallel in the lower arm if any one of the IGBTs that constitute the upper arm is in a conducting state due to a short circuit fault or a false ON signal input. In drive circuit 1 in FIG. 5, when an arm short circuit occurs, detection circuit 41 provided on individual board 31 corresponding to IGBT 62n in the lower arm detects the arm short circuit.

Specifically, suppose that an ON command is input to all IGBTs in the lower arm when IGBT 61p in the upper arm is in a conducting state. In this case, there are three paths for the short-circuit current to flow, namely, a path through IGBT 61p and IGBT 61n, a path through IGBT 61p and IGBT 62n, and a path through IGBT 61p and IGBT 63n.

In other words, the short-circuit current flowing from positive terminal P to negative terminal N flows through the upper arm IGBT 61p in a conducting state and is split at connection node U1 and flows through all IGBTs 61n, 62n, and 63n in the lower arm. If the individual differences in the IGBTs and the parasitic impedance of the wiring can be ignored, the short-circuit current flows equally through three IGBTs 61n, 62n, and 63n. In this case, the collector-emitter voltages of IGBTs 61n, 62n, and 63n in the lower arm are of the same magnitude and higher than the ON-state voltage in normal operation. Thus, detection circuits 41 as many as IGBTs connected in parallel are not necessary to detect an arm short circuit, and a single detection circuit 41, which is less than the number of IGBTs in parallel, can detect an arm short circuit.

In the above explanation, a case where IGBT 61p is short-circuited has been discussed. However, this is applicable to a case where IGBT 62p or IGBT 63p is short-circuited. In other words, whichever IGBT in the upper arm is short-circuited, the short-circuit current flows equally through the three IGBTs in the lower arm if the individual differences in the IGBTs and the parasitic impedance of the wiring can be ignored. In any case, an arm short circuit can be detected by a single detection circuit 41, which is less than the number of IGBTs in parallel.

The load short circuit will now be described. As described above, there are two cases: a case where a load is short-circuited when the upper arm is in the ON state; and a case where a load is short-circuited when the lower arm is in the ON state. Drive circuit 1 in FIG. 5 is connected to the lower arm and thus can detect a load short circuit when the lower arm is in the ON state.

Specifically, if a load short circuit occurs when the lower arm is in the ON state, a short-circuit current flows from U-phase load terminal U to negative terminal N. The short-circuit current is split at connection node U2 connected to U-phase load terminal U and flows through all IGBTs 61n, 62n, and 63n in the lower arm. If the individual differences in the elements and the parasitic impedance of the wiring can be ignored, the short-circuit current flows equally through three IGBTs 61n, 62n, and 63n. The collector-emitter voltages of IGBTs 61n, 62n, and 63n in the lower arm are of the same magnitude and higher than the ON-state voltage in normal operation. Thus, detection circuits 41 as many as IGBTs connected in parallel are not necessary to detect a load short circuit, and a single detection circuit 41, which is less than the number of IGBTs in parallel, can detect a load short circuit.

As explained above, in drive circuit 1 in FIG. 5 according to a modification of the first embodiment, detection circuit 41 is provided on any one of individual boards 30a, 31, and 30c respectively corresponding to a plurality of IGBTs 61n, 62n, and 63n connected in parallel in the lower arm. This detection circuit 41 can detect an abnormality in a plurality of IGBTs 61n, 62n, and 63n connected in parallel.

### Second Embodiment

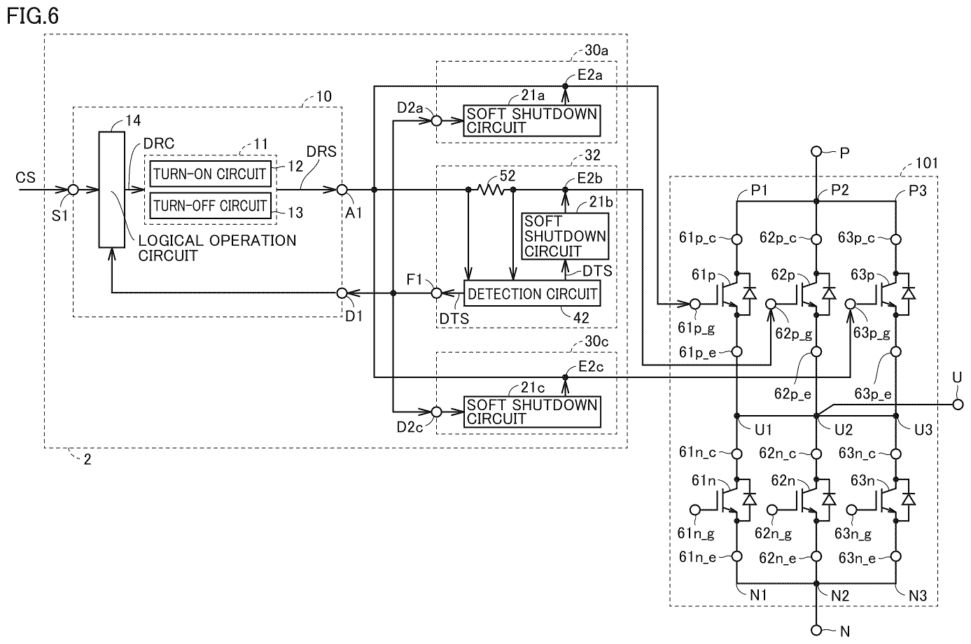

In a drive circuit 2 according to a second embodiment, the method by which a detection circuit 42 detects an abnormal state of IGBT 62p is different from that of detection circuit 41 of the first embodiment. Description will be given below with reference to FIG. 6 to FIG. 8.

### [Overall Configuration of Main Circuit and Drive Circuit]

FIG. 6 is a diagram showing a configuration example of a drive circuit according to the second embodiment. FIG. 6 shows main circuit 101 for one phase of a power conversion device and a drive circuit 2 that drives IGBTs 61p, 62p, and 63p in the upper arm of main circuit 101. The configuration of main circuit 101 in FIG. 6 is the same as in the first embodiment, and the same or corresponding parts are denoted by the same reference signs and will not be further elaborated.

Drive circuit 2 includes a common board 10 and individual boards 30a, 32, and 30c. Common board 10 generates a common drive signal DRS for controlling the on and off of IGBTs 61p, 62p, and 63p connected in parallel. Individual boards 30a, 32, and 30c correspond individually to IGBTs 61p, 62p, and 63p, respectively, and supply the generated drive signal DRS to the corresponding IGBTs. The configuration of each of common board 10 and individual boards 30a and 30c is the same as that of the first embodiment illustrated in FIG. 1, and the same or corresponding parts are denoted by the same reference signs and will not be further elaborated. The connection relationship of common board 10 and individual boards 30a and 30c with main circuit 101 is also the same as in the first embodiment and will not be further elaborated here.

Individual board 32 includes a detection signal output terminal F1, a soft shutdown circuit 21b, a detection circuit 42, and an individual gate resistor 52. The connections and functions of these components will be explained in conjunction with the explanation of the operation of drive circuit 2.

Individual boards 30a and 30c each include a not-shown individual gate resistor.

### [Operation of Drive Circuit]

The operation of drive circuit 2 in FIG. 6 will now be described. In the following, the operation of individual board 32, which is a part different from the first embodiment, will mainly be described. The operation of common board 10 and individual boards 30a and 30c is the same as in the first embodiment, except that detection circuit 42 is used instead of detection circuit 41, and a detailed description will not be repeated.

In individual board 32, individual gate resistor 52 is connected between drive signal output terminal A1 of common board 10 and gate terminal 62p_g of IGBT 62p corresponding to individual board 32. In other words, individual gate resistor 52 is provided on the wiring for drive signal DRS.

Detection circuit 42 detects an abnormal state of IGBT 62p based on the physical quantity acquired from the corresponding IGBT 62p. When an abnormal state of IGBT 62p is detected, detection circuit 42 outputs detection signal DTS to soft shutdown circuit 21b provided on individual board 32 and also outputs detection signal DTS to the outside of individual board 32 via detection signal output terminal F1. Detection signal DTS output via detection signal output terminal F1 is input to logical operation circuit 14 via detection signal input terminal D1 of common board 10. Furthermore, detection signal DTS is input to soft shutdown circuit 21a via detection signal input terminal D2a of individual board 30a and input to soft shutdown circuit 21c via detection signal input terminal D2c of individual board 30c.

The connection and operation of soft shutdown circuit 21b is the same as in the first embodiment. In other words, soft shutdown circuit 21b is connected to the wiring (more specifically, node E2b of individual board 31) for drive signal DRS that connects drive signal output terminal A1 of common board 10 to gate terminal 62p_g of IGBT 62p. When abnormality detection signal DTS is input, soft shutdown circuit 21b lowers a potential of node E2b on the wiring and clamps a gate-emitter voltage to a predetermined voltage. This can temporarily lower short-circuit current and lower a current change rate in turn-off operation by turn-off circuit 13. This can suppress a surge voltage produced during the turn-off operation of turn-off circuit 13.

The operation of detection circuit 42 provided on individual board 32 will be described in more detail below. As shown in FIG. 6, detection circuit 42 detects the potentials at both ends of individual gate resistor 52. Furthermore, although not shown in FIG. 6, detection circuit 42 is connected to emitter terminal 62p_e of the corresponding IGBT 62p to detect an emitter potential of IGBT 62p.

Detection circuit 42 detects an abnormality of IGBT 62p based on the gate charge characteristic of IGBT 62p. Specifically, detection circuit 42 detects a voltage corresponding to the amount of gate charge by integrating the voltage between both ends of individual gate resistor 52 and detects a gate-emitter voltage. The relationship between the gate-emitter voltage and the amount of gate charge is referred to as the gate charge characteristic. Since the gate charge characteristic of IGBT 62p differs between normal switching operation and short-circuiting operation, an abnormality can be detected by setting an appropriate threshold value.

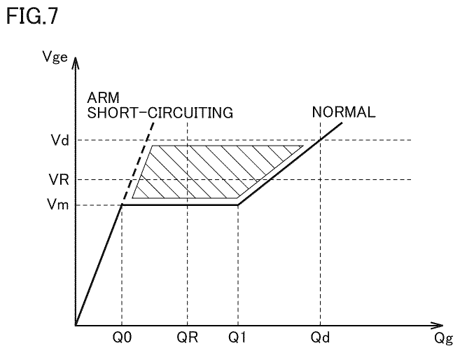

FIG. 7 is a diagram showing an example of IGBT gate charge characteristic. The vertical axis in FIG. 7 shows the gate-emitter voltage Vge, and the horizontal axis shows the amount of gate charge Qg. The gate charge characteristic in normal operation is indicated by a solid line, and the gate charge characteristic during arm short-circuiting is indicated by a broken line. Referring to FIG. 7, the behavior of IGBT in normal operation and in the event of an arm short circuit will be described below, and then a method of detecting an arm short circuit based on IGBT behavior will be described.

In normal operation, when a turn-on signal is input to the gate of IGBT from switching circuit 11, the gate-emitter voltage rises and the gate-emitter capacitance is charged. When the gate-emitter voltage exceeds a threshold voltage of IGBT, a collector current begins to flow.

When the gate-emitter capacitance is fully charged, the collector-emitter voltage begins to decrease, and the collector-gate capacitance is charged. Meanwhile, the gate-emitter voltage is a constant voltage (hereinafter referred to as Miller voltage). A period during which the gate-emitter voltage is constant in this way is called a Miller period. When the collector-emitter voltage decreases to the ON-state voltage of IGBT, the gate-emitter voltage begins to rise again and eventually rises to the power supply voltage of the gate drive circuit.

Therefore, as shown by the solid line in FIG. 7, in normal operation, the amount of charge Og supplied to the gate of IGBT increases as the gate-emitter voltage Vge rises based on the turn-on command. When the gate-emitter voltage Vge rises to Miller voltage Vm, the gate-emitter voltage Vge remains constant at Miller voltage Vm, but the amount of charge Og supplied to the gate of IGBT continues to increase. When the amount of charge Og supplied to the gate of IGBT reaches Q1, the Miller period ends and the gate-emitter voltage Vge increases again. The gate-emitter voltage Vge thereafter reaches power supply voltage Vd of the gate drive circuit. At that time, the amount of charge Qg is Qd.

On the other hand, during arm short-circuiting, the collector-emitter voltage Vce remains almost unchanged in a high voltage state. Thus, the collector-gate capacitance remains almost constant. As a result, the gate current supplied from switching circuit 11 only charges the gate-emitter capacitance. Therefore, as shown by the broken line in FIG. 7, the Miller period during which the gate-emitter voltage Vge is a constant value does not appear, and the gate-emitter voltage Vge rises immediately to power supply voltage Vd of the gate drive circuit.

In this way, there is a significant difference in gate charge characteristic, that is, the relationship between the gate-emitter voltage Vge and the amount of gate charge Qg, between normal operation and arm short-circuiting operation of IGBT.

Based on the above, referring to FIG. 6 again, a method of detecting an abnormality when an arm short circuit or a load short circuit occurs in main circuit 101 will be described. First, a case where an arm short circuit occurs will be described.

An arm short circuit occurs when an ON command is input to the IGBTs connected in parallel in the upper arm if any one of the IGBTs that constitute the lower arm is in a conducting state due to a short circuit fault or a false ON signal input. In drive circuit 2 of the second embodiment shown in FIG. 6, when an arm short circuit occurs, detection circuit 42 provided on individual board 32 corresponding to the IGBT 62p in the upper arm detects the arm short circuit.

Specifically, suppose that an ON command is input to the IGBTs in the upper arm when IGBT 61n in the lower arm is in a conducting state. In this case, there are three paths for the short-circuit current to flow, namely, a path through IGBT 61p and IGBT 61n, a path through IGBT 62p and IGBT 61n, and a path through IGBT 63p and IGBT 61n.

In other words, the short-circuit current flowing from positive terminal P to negative terminal N is split at positive node P2 of the upper arm and flows through all IGBTs 61p, 62p, and 63p in the upper arm. If the individual differences in the elements and the parasitic impedance of the wiring can be ignored, the short-circuit current flows equally through three IGBTs 61p, 62p, and 63p. The collector-emitter voltages of IGBTs 61p, 62p, and 63p in the upper arm are of the same magnitude and higher than the ON-state voltage in normal operation. The gate-emitter voltages Vge of these IGBTs are of the same magnitude. Thus, detection circuits 42 as many as IGBTs connected in parallel are not necessary to detect an arm short circuit, and a single detection circuit 42, which is less than the number of IGBTs in parallel, can detect an arm short circuit.

As explained with reference to FIG. 7, the collector-gate capacitance of IGBT is highly dependent on the collector-emitter voltage. Therefore, the difference in collector-emitter voltage between normal operation and arm short-circuiting operation can be detected as a difference in gate charge characteristic. For example, as shown in FIG. 7, whether normal or abnormal can be detected depending on whether the amount of charge Qg supplied to the gate of IGBT before the gate-emitter voltage Vge reaches a voltage value VR is higher than a threshold value QR.

In the above explanation, a case where IGBT 61n is short-circuited has been discussed. However, this is applicable to a case where IGBT 62n or IGBT 63n is short-circuited. In other words, whichever IGBT in the lower arm is short-circuited, the short-circuit current flows equally through the three IGBTs in the upper arm if the individual differences in the IGBTs and the parasitic impedance of the wiring can be ignored. In any case, an arm short circuit can be detected by a single detection circuit 41, which is less than the number of IGBTs in parallel.

Next, a case where a load short circuit occurs will be described. There are two cases of a load short circuit: a case where a load is short-circuited when the upper arm is in the ON state; and a case where a load is short-circuited when the lower arm is in the ON state. Detection circuit 42 provided in drive circuit 2 in FIG. 6 is connected to the upper arm and thus can detect a load short circuit when the upper arm is in the ON state.

When the upper arm enters the ON state, the collector-emitter voltage of the IGBTs in the upper arm temporarily decreases to the ON-state voltage in the same manner as in normal turn-on operation. Subsequently, when a load short circuit occurs, the inductance of the load becomes smaller than in normal operation, and a higher collector current flows than in normal operation. As a result, the collector current increases rapidly and the collector-emitter voltage rises again. As the collector-emitter voltage rises again, a displacement current flows from the collector terminal to the gate terminal, the gate-emitter voltage rises, and the amount of gate charge is reduced. Therefore, a load short circuit can be detected by detecting that the gate-emitter voltage is higher than in normal operation and that the amount of gate charge is reduced.

Specifically, if a load short circuit occurs when the upper arm is in the ON state, a short-circuit current flows from positive terminal P to U-phase load terminal U. The short-circuit current is split at positive node P2 of the upper arm and flows through all IGBTs 61p, 62p, and 63p in the upper arm. If the individual differences in the elements and the parasitic impedance of the wiring can be ignored, the short-circuit current flows equally through three IGBTs 61p, 62p, and 63p. The collector-emitter voltages of IGBTs 61p, 62p, and 63p in the upper arm are of the same magnitude and decrease once and then rise again. Thus, detection circuits 42 as many as IGBTs connected in parallel are not necessary to detect a load short circuit, and a single detection circuit 42, which is less than the number of IGBTs in parallel, can detect a load short circuit.

### [Effects of Second Embodiment]

As explained above, in drive circuit 2 according to the second embodiment, detection circuit 42 is provided in any one of the individual boards (individual boards 30a, 32, and 30c above) respectively corresponding to a plurality of power semiconductor switching elements (IGBTs 61p, 62p, and 63p above) connected in parallel. This detection circuit 42 can detect an abnormality in a plurality of power semiconductor switching elements connected in parallel.

Specifically, detection circuit 42 detects the voltage between both ends of individual gate resistor 52 and detects the gate-emitter voltage of IGBT 62p. Detection circuit 42 detects an abnormality of IGBT 62p, based on the gate charge characteristic of IGBT 62p obtained from these detected values.

### [Modification of Second Embodiment]

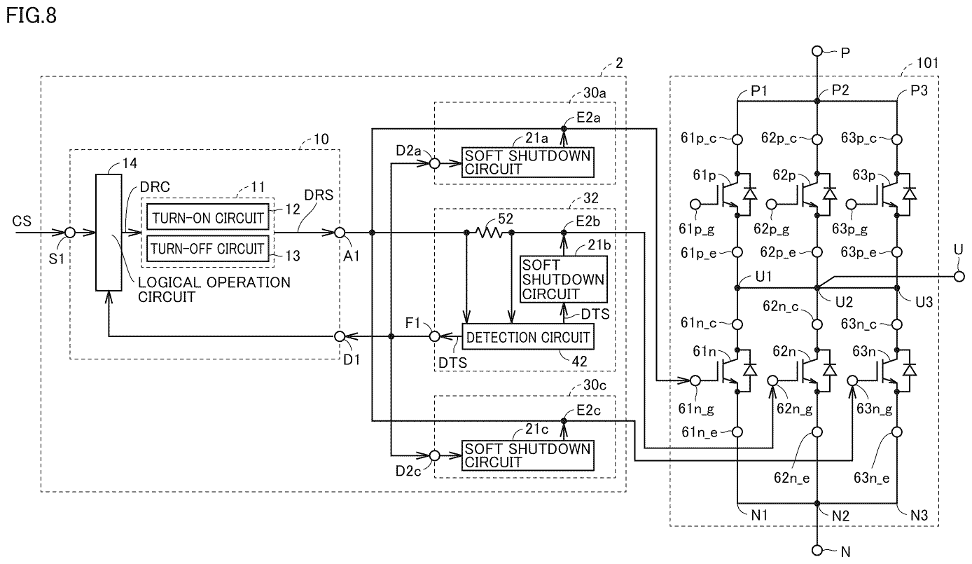

Drive circuit 2 in FIG. 6 may be configured to drive the lower arm of main circuit 101. Alternatively, a drive circuit that drives the upper arm of main circuit 101 and a drive circuit that drives the lower arm of main circuit 101 may be provided separately. Referring to FIG. 8, a case where drive circuit 2 drives the lower arm of main circuit 101 will be described below.

FIG. 8 is a diagram showing a configuration example of a drive circuit according to a modification of the second embodiment. Drive circuit 2 in FIG. 8 differs from drive circuit 2 in FIG. 6 in that it drives IGBTs 61n, 62n, and 63n that constitute the lower arm of main circuit 101, instead of IGBTs 61p, 62p, and 63p that constitute the upper arm of main circuit 101. Drive circuit 2 in FIG. 8 has a function to detect an abnormal state of IGBTs 61n, 62n, and 63n connected in parallel to protect a plurality of power semiconductor elements from an abnormal state.

More specifically, the configuration of drive circuit 2 in FIG. 8 and the configuration of main circuit 101 in FIG. 8 are the same as in FIG. 6, but the connection between them differs from that in FIG. 6. In the following, differences from the case in FIG. 6 will mainly be described, and the same or corresponding parts as in FIG. 6 are denoted by the same reference signs and will not be further elaborated.

As shown in FIG. 8, common board 10 that constitutes drive circuit 2 generates a common drive signal DRS for controlling the on and off of IGBTs 61n, 62n, and 63n connected in parallel that constitute the lower arm. Individual boards 30a, 32, and 30c that constitute drive circuit 2 correspond individually to IGBTs 61n, 62n, and 63n, respectively, and supply the generated drive signal DRS to the corresponding IGBTs.

Specifically, gate terminal 61n_g of IGBT 61n that constitutes the lower arm is connected to drive signal output terminal A1 of common board 10 via the corresponding individual board 30a. Similarly, gate terminal 62n_g of IGBT 62n that constitutes the lower arm is connected to drive signal output terminal A1 of common board 10 via the corresponding individual board 32. Similarly, gate terminal 63n_g of IGBT 63n that constitutes the lower arm is connected to drive signal output terminal A1 of common board 10 via the corresponding individual board 30c.

In individual board 32, individual gate resistor 52 is connected between drive signal output terminal A1 of common board 10 and gate terminal 62n_g of IGBT 62n corresponding to individual board 32. In other words, individual gate resistor 52 is provided on the wiring for drive signal DRS.

Individual boards 30a and 30c each include a not-shown individual gate resistor.

Soft shutdown circuit 21a on individual board 30a is connected to wiring for the drive signal (more specifically, node E2a of individual board 30a) that connects drive signal output terminal A1 of common board 10 to gate terminal 61n_g of IGBT 61n. Soft shutdown circuit 21b on individual board 32 is connected to wiring for drive signal DRS (more specifically, node E2b of individual board 32) that connects drive signal output terminal A1 of common board 10 to gate terminal 62n_g of IGBT 62n. Node E2b is closer to gate terminal 62n_g than individual gate resistor 52. Soft shutdown circuit 21c on individual board 30c is connected to wiring for the drive signal (more specifically, node E2c of individual board 30c) that connects drive signal output terminal A1 of common board 10 to gate terminal 63n_g of IGBT 63n.

When abnormality detection signal DTS is input from detection circuit 42, soft shutdown circuits 21a to 21c respectively lower potentials of nodes E2a to E2c and clamp gate-emitter voltages to a predetermined voltage, in the same manner as in FIG. 6. This can temporarily lower short-circuit current and lower a current change rate in turn-off operation by turn-off circuit 13.

Detection circuit 42 of individual board 32 is connected to both ends of individual gate resistor 52 to detect the voltage between both ends of individual gate resistor 52. Although not shown in FIG. 8, detection circuit 42 is connected to emitter terminal 62n_e of IGBT 62n that constitutes the lower arm to detect the gate-emitter voltage.

Detection circuit 42 detects an abnormality of IGBT 62n based on the gate charge characteristic of IGBT 62n obtained from these detected values. Specifically, detection circuit 42 detects a voltage corresponding to the amount of gate charge by integrating the voltage between both ends of individual gate resistor 52 and detects a gate-emitter voltage. Since the gate charge characteristic of IGBT 62n differs between normal switching operation and short-circuiting operation, an abnormality can be detected by setting an appropriate threshold value.

The operation of detection circuit 42 in drive circuit 2 in FIG. 8 in a case of arm short circuit and in a case of load short circuit will be described specifically below.

An arm short circuit occurs when an ON command is input to the IGBT's connected in parallel in the lower arm if any one of the IGBTs that constitute the upper arm is in a conducting state due to a short circuit fault or a false ON signal input. In drive circuit 2 of the second embodiment shown in FIG. 8, when an arm short circuit occurs, detection circuit 42 provided on individual board 32 corresponding to IGBT 62n in the lower arm detects the arm short circuit.

Specifically, suppose that an ON command is input to all IGBTs in the lower arm when IGBT 61p in the upper arm is in a conducting state. In this case, there are three paths for the short-circuit current to flow, namely, a path through IGBT 61p and IGBT 61n, a path through IGBT 61p and IGBT 62n, and a path through IGBT 61p and IGBT 63n.

In other words, the short-circuit current flowing from positive terminal P to negative terminal N flows through the upper arm IGBT 61p in a conducting state and is split at connection node U1 and flows through all IGBTs 61n, 62n, and 63n in the lower arm. If the individual differences in the IGBTs and the parasitic impedance of the wiring can be ignored, the short-circuit current flows equally through three IGBTs 61n, 62n, and 63n. The collector-emitter voltages of IGBTs 61n, 62n, and 63n in the lower arm are of the same magnitude and higher than the ON-state voltage in normal operation. The gate-emitter voltages Vge of these IGBTs are also of the same magnitude. Thus, detection circuits 42 as many as IGBTs connected in parallel are not necessary to detect an arm short circuit, and a single detection circuit 42, which is less than the number of IGBTs in parallel, can detect an arm short circuit.

As explained with reference to FIG. 7, the collector-gate capacitance of IGBT is highly dependent on the collector-emitter voltage. Therefore, the difference in collector-emitter voltage between normal operation and main circuit short-circuiting operation can be detected as a difference in gate charge characteristic. For example, as shown in FIG. 7, whether normal or abnormal can be detected depending on whether the amount of charge Qg supplied to the gate of IGBT before the gate-emitter voltage Vge reaches a voltage value VR is higher than a threshold value QR.

In the above explanation, a case where IGBT 61p is short-circuited has been discussed. However, this is applicable to a case where IGBT 62p or IGBT 63p is short-circuited. In other words, whichever IGBT in the upper arm is short-circuited, the short-circuit current flows equally through the three IGBTs in the lower arm if the individual differences in the IGBTs and the parasitic impedance of the wiring can be ignored. In any case, an arm short circuit can be detected by a single detection circuit 42, which is less than the number of IGBTs in parallel.

Next, a case where a load short circuit occurs will be described. There are two cases of a load short circuit: a case where a load is short-circuited when the upper arm is in the ON state; and a case where a load is short-circuited when the lower arm is in the ON state. Detection circuit 42 provided in drive circuit 2 in FIG. 8 is connected to the lower arm and thus can detect a load short circuit when the lower arm is in the ON state.

When the lower arm enters the ON state, the collector-emitter voltage of the IGBTs in the lower arm temporarily decreases to the ON-state voltage in the same manner as in normal turn-on operation. Subsequently, when a load short circuit occurs, the inductance of the load becomes smaller than in normal operation, and a higher collector current flows than in normal operation. As a result, the collector current increases rapidly and the collector-emitter voltage rises again. As the collector-emitter voltage rises again, a displacement current flows from the collector terminal to the gate terminal, the gate-emitter voltage rises, and the amount of gate charge is reduced. Therefore, a load short circuit can be detected by detecting that the gate-emitter voltage is higher than in normal operation and that the amount of gate charge is reduced.

Specifically, if a load short circuit occurs when the lower arm is in the ON state, a short-circuit current flows from U-phase load terminal U to negative terminal N. The short-circuit current is split at connection node U2 connected to U-phase load terminal U and flows through all IGBTs 61n, 62n, and 63n in the lower arm. If the individual differences in the elements and the parasitic impedance of the wiring can be ignored, the short-circuit current flows equally through three IGBTs 61n, 62n, and 63n. The collector-emitter voltages of IGBTs 61n, 62n, and 63n in the lower arm are of the same magnitude and decrease once and then rise again. Thus, detection circuits 42 as many as IGBTs connected in parallel are not necessary to detect a load short circuit, and a single detection circuit 42, which is less than the number of IGBTs in parallel, can detect a load short circuit.

As explained above, in drive circuit 2 in FIG. 8 according to a modification of the second embodiment, detection circuit 42 is provided on any one of individual boards 30a, 32, and 30c respectively corresponding to a plurality of IGBTs 61n, 62n, and 63n connected in parallel in the lower arm. This detection circuit 42 can detect an abnormality in a plurality of IGBTs 61n, 62n, and 63n connected in parallel.

### Third Embodiment

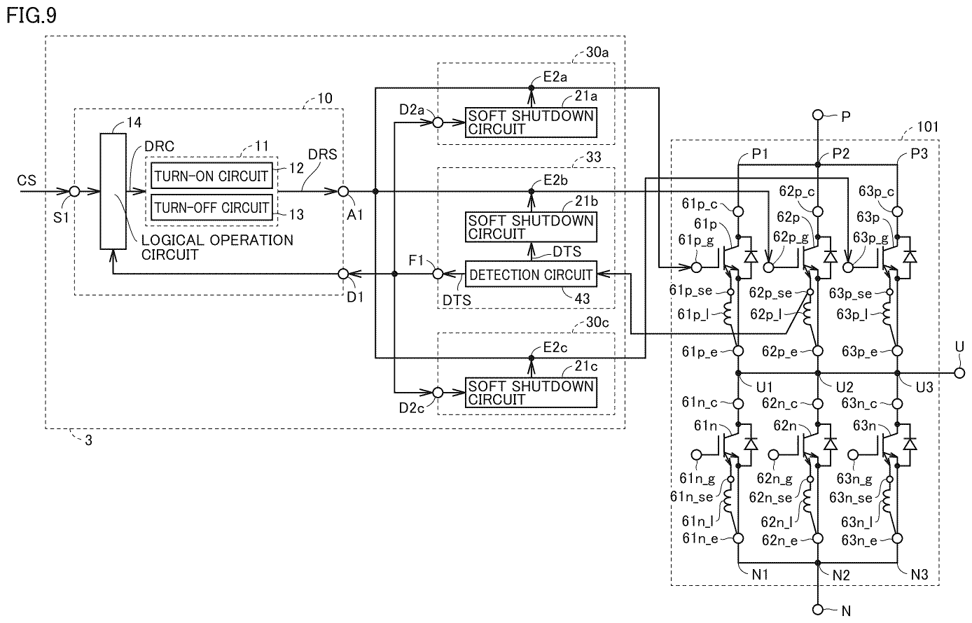

In a drive circuit 3 according to a third embodiment, the method by which a detection circuit 43 detects an abnormal state of IGBT 62p is different from those of detection circuit 41 of the first embodiment and detection circuit 42 of the second embodiment. Description will be given below with reference to FIG. 9.

### [Overall Configuration of Main Circuit and Drive Circuit]

FIG. 9 is a diagram showing a configuration example of a drive circuit according to the third embodiment. FIG. 9 shows main circuit 101 for one phase of a power conversion device and a drive circuit 3 that drives IGBTs 61p, 62p, and 63p in the upper arm of main circuit 101.

Main circuit 101 in FIG. 9 differs from main circuit 101 in FIG. 1 and FIG. 6 in that IGBTs 61p, 62p, 63p, 61n, 62n, and 63n further include sense emitter terminals 61p_se, 62p_se, 63p_se, 61n_se, 62n_se, and 63n se, respectively. In each IGBT, the sense-emitter terminal is connected to the emitter terminal by wiring, and the wiring has a parasitic inductance (61p_1, 62p_1, 63p_1, 61n 1, 62n_1, 63n_l). For example, a parasitic inductance 61p_1 exists between sense emitter terminal 61p_se and emitter terminal 61p_e of IGBT 61p. This is applicable to the other IGBTs. The other configuration of main circuit 101 in FIG. 9 is the same as in FIG. 1 and FIG. 6, and the same or corresponding parts are denoted by the same reference signs and will not be further elaborated.

In the present disclosure, the collector terminal is also referred to as first main terminal, the emitter terminal is also referred to as second main terminal, and the sense emitter terminal is also referred to as sense terminal. The sense terminal is provided to split part of the main current flowing from the first main terminal to the second main terminal.

Drive circuit 2 includes a common board 10 and individual boards 30a, 33, and 30c. Common board 10 generates a common drive signal DRS for controlling the on and off of IGBTs 61p, 62p, and 63p connected in parallel. Individual boards 30a, 33, and 30c correspond individually to IGBTs 61p, 62p, and 63p, respectively, and supply the generated drive signal DRS to the corresponding IGBTs. The configuration and operation of each of common board 10 and individual boards 30a and 30c is the same as those in the first embodiment illustrated in FIG. 1 and in the second embodiment illustrated in FIG. 6, and the same or corresponding parts are denoted by the same reference signs and will not be further elaborated. The connection relationship of common board 10 and individual boards 30a and 30c with main circuit 101 is also the same as in the first and second embodiments and will not be further elaborated here.

Individual board 33 includes a detection signal output terminal F1, a soft shutdown circuit 21b, and a detection circuit 43. The connections and functions of these components will be explained in conjunction with the explanation of the operation of drive circuit 2.

### [Operation of Drive Circuit]

The operation of drive circuit 3 in FIG. 9 will now be described. In the following, the operation of individual board 33, which is a part different from the first and second embodiments, will mainly be described. The operation of common board 10 and individual boards 30a and 30c is the same as in the first and second embodiments, except that detection circuit 43 is used instead of detection circuit 41 or 42, and a detailed description will not be repeated.

Detection circuit 43 detects an abnormal state of IGBT 62p based on the physical quantity acquired from the corresponding IGBT 62p. When an abnormal state of IGBT 62p is detected, detection circuit 43 outputs detection signal DTS to soft shutdown circuit 21b provided on individual board 33 and also outputs detection signal DTS to the outside of individual board 33 via detection signal output terminal F1. Detection signal DTS output via detection signal output terminal F1 is input to logical operation circuit 14 via detection signal input terminal D1 of common board 10. Furthermore, detection signal DTS is input to soft shutdown circuit 21a via detection signal input terminal D2a of individual board 30a and input to soft shutdown circuit 21c via detection signal input terminal D2c of individual board 30c.

The connection and operation of soft shutdown circuit 21b is the same as in the first and second embodiments. In other words, soft shutdown circuit 21b is connected to the wiring for drive signal DRS (more specifically, node E2b of individual board 31) that connects drive signal output terminal A1 of common board 10 to gate terminal 62p_g of IGBT 62p. When detection signal DTS is input, soft shutdown circuit 21b lowers a potential of node E2b on the wiring and clamps a gate-emitter voltage to a predetermined voltage. This can temporarily lower short-circuit current and lower a current change rate in turn-off operation by turn-off circuit 13.

The operation of detection circuit 43 provided on individual board 33 will be described in more detail below. As shown in FIG. 9, detection circuit 43 is connected to sense emitter terminal 62p_se of IGBT 62p. Furthermore, although not shown in FIG. 9, detection circuit 43 is connected to emitter terminal 62p_e of IGBT 62p. An abnormality in main circuit 101 is detected, based on the voltage between sense emitter terminal 62p_se and emitter terminal 62p_e of IGBT 62p detected by these. As described above, sense emitter terminal 62p_se and emitter terminal 62p_e are connected by wiring. A parasitic inductance 62p_1 exists in this wiring. In the event of a short circuit, due to a rapid current variation (di/dt) in main circuit current and this parasitic inductance 62p_1, a larger induced voltage is produced between sense emitter terminal 62p_se and emitter terminal 62p_e than in normal operation. Therefore, by setting an appropriate threshold value, occurrence of an abnormality can be detected based on detection of this large induced voltage.

Based on the above, referring to FIG. 9, a method of detecting an abnormality when an arm short circuit or a load short circuit occurs in main circuit 101 will be described. First, a case where an arm short circuit occurs will be described.

An arm short circuit occurs when an ON command is input to the IGBTs connected in parallel in the upper arm if any one of the IGBTs that constitute the lower arm is in a conducting state due to a short circuit fault or a false ON signal input. In drive circuit 3 of the third embodiment shown in FIG. 9, when an arm short circuit occurs, detection circuit 43 provided on individual board 33 corresponding to the IGBT 62p in the upper arm detects the arm short circuit.

Specifically, suppose that an ON command is input to all IGBTs in the upper arm when IGBT 61n in the lower arm is in a conducting state. In this case, there are three paths for the short-circuit current to flow, namely, a path through IGBT 61p and IGBT 61n, a path through IGBT 62p and IGBT 61n, and a path through IGBT 63p and IGBT 61n.

In other words, the short-circuit current flowing from positive terminal P to negative terminal N is split at positive node P2 of the upper arm and flows through all IGBTs 61p, 62p, and 63p in the upper arm. If the individual differences in the IGBTs and the parasitic impedance of the wiring can be ignored, the short-circuit current flows equally through three IGBTs 61p, 62p, and 63p. The short-circuit currents of the same magnitude flow through IGBTs 61p, 62p, and 63p in the upper arm during the on drive, and the sense emitter-emitter voltages rise similarly. Therefore, detection circuits 43 as many as IGBTs connected in parallel are not necessary to detect an arm short circuit, and a single detection circuit 43, which is less than the number of IGBTs in parallel, can detect an arm short circuit. An arm short circuit can be detected similarly in whichever of individual boards 30a, 33, and 30c detection circuit 43 is provided.

In the above explanation, a case where IGBT 61n is short-circuited has been discussed. However, this is applicable to a case where IGBT 62n or IGBT 63n is short-circuited. In other words, whichever IGBT in the lower arm is short-circuited, the short-circuit current flows equally through the three IGBTs in the upper arm if the individual differences in the IGBTs and the parasitic impedance of the wiring can be ignored. In any case, an arm short circuit can be detected by a single detection circuit 43, which is less than the number of IGBTs in parallel.

Next, a case where a load short circuit occurs will be described. There are two cases of a load short circuit: a case where a load is short-circuited when the upper arm is in the ON state; and a case where a load is short-circuited when the lower arm is in the ON state. Detection circuit 43 provided in drive circuit 3 in FIG. 9 is connected to the upper arm and thus can detect a load short circuit when the upper arm is in the ON state.

Specifically, if a load short circuit occurs when the upper arm is in the ON state, a short-circuit current flows from positive terminal P to U-phase load terminal U. The short-circuit current is split at positive node P2 of the upper arm and flows through all IGBT's 61p, 62p, and 63p in the upper arm. If the individual differences in the IGBTs and the parasitic impedance of the wiring can be ignored, the short-circuit current flows equally through three IGBTs 61p, 62p, and 63p. The short-circuit currents of the same magnitude flow through IGBTs 61p, 62p, and 63p in the upper arm during the on drive, and the sense emitter-emitter voltages increase similarly. Thus, detection circuits 43 as many as IGBTs connected in parallel are not necessary to detect a load short circuit, and a single detection circuit 43, which is less than the number of IGBTs in parallel, can detect a load short circuit.

### [Effects of Third Embodiment]

As explained above, in drive circuit 3 according to the third embodiment, detection circuit 43 is provided in any one of the individual boards (individual boards 30a, 33, and 30c above) respectively corresponding to a plurality of power semiconductor switching elements (IGBTs 61p, 62p, and 63p above) connected in parallel. This detection circuit 43 can detect an abnormality in a plurality of power semiconductor switching elements connected in parallel.

Specifically, detection circuit 43 detects an abnormality in main circuit 101 by detecting a voltage generated in the parasitic impedance of the wiring connecting sense emitter terminal 62p se and emitter terminal 62p_e of the corresponding IGBT 62p.

### [Modification of Third Embodiment]

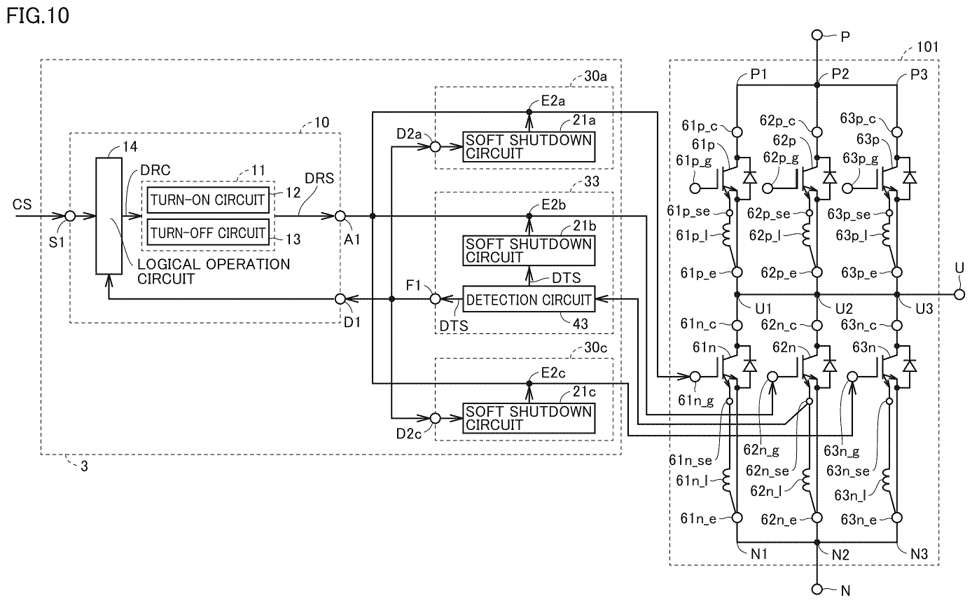

Drive circuit 3 in FIG. 9 may be configured to drive the lower arm of main circuit 101. Alternatively, a drive circuit that drives the upper arm of main circuit 101 and a drive circuit that drives the lower arm of main circuit 101 may be provided separately. Referring to FIG. 10, a case where drive circuit 3 drives the lower arm of main circuit 101 will be described below.

FIG. 10 is a diagram showing a configuration example of a drive circuit according to a modification of the third embodiment. Drive circuit 3 in FIG. 10 differs from drive circuit 3 in FIG. 9 in that it drives IGBTs 61n, 62n, and 63n that constitute the lower arm of main circuit 101, instead of IGBTs 61p, 62p, and 63p that constitute the upper arm of main circuit 101. Drive circuit 3 in FIG. 10 has a function to detect an abnormal state of IGBTs 61n, 62n, and 63n connected in parallel to protect a plurality of power semiconductor elements from an abnormal state.

More specifically, the configuration of drive circuit 3 in FIG. 10 and the configuration of main circuit 101 in FIG. 10 are the same as in FIG. 9, but the connection between them differs from that in FIG. 9. In the following, differences from the case in FIG. 9 will mainly be described, and the same or corresponding parts as in FIG. 9 are denoted by the same reference signs and will not be further elaborated.

As shown in FIG. 10, common board 10 that constitutes drive circuit 3 generates a common drive signal DRS for controlling the on and off of IGBTs 61n, 62n, and 63n connected in parallel that constitute the lower arm. Individual boards 30a, 33, and 30c that constitute drive circuit 3 correspond individually to IGBTs 61n, 62n, and 63n, respectively, and supply the generated drive signal DRS to the corresponding IGBTs.

Specifically, gate terminal 61n_g of IGBT 61n that constitutes the lower arm is connected to drive signal output terminal A1 of common board 10 via the corresponding individual board 30a. Similarly, gate terminal 62n_g of IGBT 62n that constitutes the lower arm is connected to drive signal output terminal A1 of common board 10 via the corresponding individual board 33. Similarly, gate terminal 63n_g of IGBT 63n that constitutes the lower arm is connected to drive signal output terminal A1 of common board 10 via the corresponding individual board 30c.

Soft shutdown circuit 21a on individual board 30a is connected to wiring for the drive signal (more specifically, node E2a of individual board 30a) that connects drive signal output terminal A1 of common board 10 to gate terminal 61n_g of IGBT 61n. Soft shutdown circuit 21b on individual board 33 is connected to wiring for drive signal DRS (more specifically, node E2b of individual board 33) that connects drive signal output terminal A1 of common board 10 to gate terminal 62n_g of IGBT 62n. Soft shutdown circuit 21c on individual board 30c is connected to wiring for the drive signal (more specifically, node E2c of individual board 30c) that connects drive signal output terminal A1 of common board 10 to gate terminal 63n_g of IGBT 63n.

When abnormality detection signal DTS is input from detection circuit 43, soft shutdown circuits 21a to 21c respectively lower potentials of nodes E2a to E2c and clamp gate-emitter voltages to a predetermined voltage, in the same manner as in FIG. 9. This can temporarily lower short-circuit current and lower a current change rate in turn-off operation by turn-off circuit 13. As a result, IGBTs 61n, 62n, and 63n are set to the OFF state at a slower speed than in the turn-off operation in normal operation.

Detection circuit 43 on individual board 33 is connected to sense emitter terminal 62n se and emitter terminal 62n_e of the corresponding IGBT 62n and detects the voltage between these terminals. Detection circuit 43 determines an abnormality in main circuit 101 based on the detected sense emitter-emitter voltage of IGBT 62n.

The operation of detection circuit 43 in drive circuit 3 in FIG. 10 will be described below. Detection circuit 43 determines an abnormality in main circuit 101 based on the sense emitter-emitter voltage of IGBT 62n.

Three IGBTs 61n, 62n, and 63n connected in parallel are connected with the collector-emitter in common, and if the individual differences in the IGBTs and the parasitic impedance of the wiring can be ignored, the respective voltages applied to IGBTs 61n, 62n, and 63n connected in parallel are equal. Similarly, the respective currents flowing through IGBTs 61n, 62n, and 63n are also equal.

Detection circuit 43 provided on individual board 33 detects an abnormality based on the sense emitter-emitter voltage of the corresponding IGBT 62n. Since sense emitter terminal 62n se and emitter terminal 62n_e of IGBT 62n are connected via wiring, a parasitic inductance 62n_1 exists between the sense emitter and the emitter of IGBT 62n. In the event of a short circuit, a larger induced voltage than in normal operation is generated due to a rapid current variation (di/dt) in main circuit current and parasitic inductance 62n I between the sense emitter and the emitter. Therefore, an abnormality can be detected by setting an appropriate threshold value.

The operation of detection circuit 43 in drive circuit 3 in FIG. 10 in a case of arm short circuit and in a case of load short circuit will now be described specifically.

An arm short circuit occurs when an ON command is input to the IGBTs connected in parallel in the lower arm if any one of the IGBTs that constitute the upper arm is in a conducting state due to a short circuit fault or a false ON signal input. In drive circuit 3 in FIG. 10, when an arm short circuit occurs, detection circuit 43 provided on individual board 33 corresponding to the IGBT 62n in the lower arm detects the arm short circuit.

Specifically, suppose that an ON command is input to all IGBTs in the lower arm when IGBT 61p in the upper arm is in a conducting state. In this case, there are three paths for the short-circuit current to flow, namely, a path through IGBT 61p and IGBT 61n, a path through IGBT 61p and IGBT 62n, and a path through IGBT 61p and IGBT 63n.

In other words, the short-circuit current flowing from positive terminal P to negative terminal N flows through the upper arm IGBT 61p in a conducting state and is split at connection node U1 and flows through all IGBTs 61n, 62n, and 63n in the lower arm. If the individual differences in the IGBTs and the parasitic impedance of the wiring can be ignored, the short-circuit current flows equally through three IGBTs 61n, 62n, and 63n. The short-circuit currents of the same magnitude flow through IGBTs 61n, 62n, and 63n in the lower arm during the on drive, and the sense emitter-emitter voltages of these IGBTs rise similarly, Thus, detection circuits 43 as many as IGBTs connected in parallel are not necessary to detect an arm short circuit, and a single detection circuit 43, which is less than the number of IGBTs in parallel, can detect an arm short circuit.

In the above explanation, a case where IGBT 61p is short-circuited has been discussed. However, this is applicable to a case where IGBT 62p or IGBT 63p is short-circuited. In other words, whichever IGBT in the upper arm is short-circuited, the short-circuit current flows equally through the three IGBTs in the lower arm if the individual differences in IGBTs and the parasitic impedance of the wiring can be ignored. In any case, an arm short circuit can be detected by a single detection circuit 43, which is less than the number of IGBTs in parallel.

The load short circuit will now be described. There are two cases of a load short circuit: a case where a load is short-circuited when the upper arm is in the ON state; and a case where a load is short-circuited when the lower arm is in the ON state. Drive circuit 3 in FIG. 10 is connected to the lower arm and thus can detect a load short circuit when the lower arm is in the ON state.

Specifically, if a load short circuit occurs when the lower arm is in the ON state, a short-circuit current flows from U-phase load terminal U to negative terminal N. The short-circuit current is split at connection node U2 connected to U-phase load terminal U and flows through all IGBTs 61n, 62n, and 63n in the lower arm. If the individual differences in the IGBTs and the parasitic impedance of the wiring can be ignored, the short-circuit current flows equally through three IGBTs 61n, 62n, and 63n. The short-circuit currents of the same magnitude flow through IGBTs 61n, 62n, and 63n in the lower arm during the on drive, and the sense emitter-emitter voltages rise similarly. Thus, detection circuits 43 as many as IGBTs connected in parallel are not necessary to detect an arm short circuit, and a single detection circuit 43, which is less than the number of IGBTs in parallel, can detect an arm short circuit.

As explained above, in drive circuit 3 in FIG. 10 according to a modification of the third embodiment, detection circuit 43 is provided on any one of individual boards 30a, 31, and 30c respectively corresponding to a plurality of IGBTs 61n, 62n, and 63n connected in parallel in the lower arm. This detection circuit 43 can detect an abnormality in a plurality of IGBTs 61n, 62n, and 63n connected in parallel.

### Fourth Embodiment

In a fourth embodiment, a case where the individual differences in the characteristics of a plurality of power semiconductor elements connected in parallel and the parasitic impedance of the wiring are not negligible will be described.

In a plurality of IGBTs connected in parallel described in the first to third embodiments, the collector terminal of each IGBT is connected to a common high potential-side node and the emitter terminal of each IGBT is connected to a common low potential-side node. In this case, if the individual differences in the IGBTs and the impedance of the wiring can be ignored, the voltage applied to each of a plurality of IGBTs connected in parallel is equal and the current flowing through each of a plurality of IGBTs is also equal.

Furthermore, detection circuits 41 to 43 illustrated in the first to third embodiments, respectively, performs an abnormality determination based on the characteristic of voltage or current of one corresponding IGBT. In this case, if the voltage of each IGBT and the current flowing through each IGBT are the same among the IGBTs, similar determination can be made based on the voltage or current characteristic of any of IGBTs connected in parallel.

In practice, however, in a system in which a plurality of power semiconductor elements are connected in parallel, the individual differences in IGBTs and the parasitic impedance of the wiring are usually not negligible. In this case, there are variations in voltage of each IGBT and current flowing through each IGBT. In addition, the determination result may vary depending on which of IGBTs detection circuits 41 to 43 are connected to.

In the following, first, the reason why voltage and current of each of a plurality of power semiconductor elements connected in parallel vary will be explained. Next, it will be explained that the paths through which short-circuit current is likely to flow differ depending on the conditions of occurrence of arm short circuit and load short circuit. Furthermore, the difference in current and voltage of each power semiconductor element between when two power semiconductor elements are arranged adjacent to each other and when they are arranged at a distance from each other will be explained.

### [Reason for Voltage and Current Variations in Each IGBT]

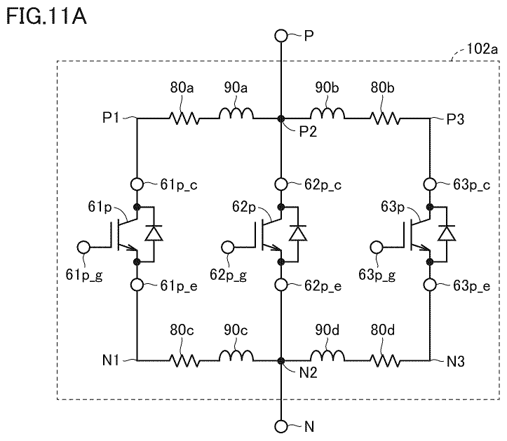

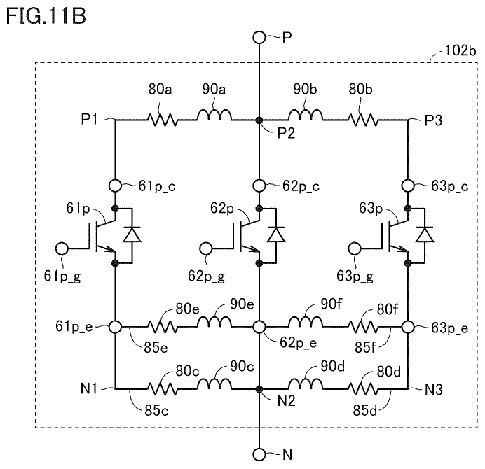

FIG. 11A is a diagram for explaining the reason why current and voltage of each IGBT vary in a plurality of IGBTs connected in parallel.

A main circuit 102a shown in FIG. 11A includes three IGBTs 61p, 62p, and 63p connected in parallel. IGBT 61p is connected between positive node P1 and negative node N1, IGBT 62p is connected between positive node P2 and negative node N2, and IGBT 63p is connected between P3 and negative node N3. Positive node P2 is connected to positive nodes P1 and P3 and connected to positive terminal P. Negative node N2 is connected to negative nodes N1 and N3 and connected to negative terminal N. Therefore, collector terminals 61p_c, 62p_c, and 63p_c of three IGBTs 61p, 62p, and 63p are connected to positive terminal P via the common positive node P2. Emitter terminals 61p_e, 62p_e, and 63p_e of three IGBTs 61p, 62p, and 63p are connected to negative terminal N via the common negative node N1 in the lower arm.

In this case, a parasitic resistor 80a and a parasitic inductance 90a exist in the wiring between positive node P1 and positive node P2. A parasitic resistor 80b and a parasitic inductance 90b exist in the wiring between positive node P2 and positive node P3. A parasitic resistor 80c and a parasitic inductance 90c exist in the wiring between negative node N1 and negative node N2. A parasitic resistor 80d and a parasitic inductance 90d exist in the wiring between negative node N2 and negative node N3.

When IGBTs 61p, 62p, and 63p are in the ON state, the current flowing from positive terminal P to negative terminal N is split at positive node P2. There are three current paths after the current is split. The balance of current split to each path is determined by the impedance of the current path. In other words, differences in impedance of the current paths cause a variation in voltage and current of the IGBTs. This variation is large especially when a steep and high current flows, such as in the event of a short circuit.

Next, the reason why the on-resistance of each power semiconductor element differs in a plurality of power semiconductor elements connected in parallel will be explained.

The impedance of each current path is the sum of the parasitic impedance of the wiring and the on-resistance of the IGBT. For example, in FIG. 11A, the impedance of the current path from positive terminal P to negative terminal N through IGBT 61p is the sum of parasitic resistors 80a and 80c, the parasitic inductances 90a and 90c, and the on-resistance of IGBT 61p.

The on-resistance is the resistance between the collector and the emitter when the IGBT is in the ON state and is dependent on the gate-emitter voltage. The on-resistance is affected by individual differences in IGBTs themselves, but since IGBTs with small individual differences are usually connected in parallel, the individual differences in IGBTs themselves are ignored here.

FIG. 11B is a diagram for explaining the reason why the on-resistance of each IGBT varies in a plurality of IGBT's connected in parallel.

A main circuit 102b shown in FIG. 11B differs from main circuit 102a in FIG. 11A in that it further includes emitter wiring 85e and 85f for connecting emitter terminals 61p_c, 62p_e, and 63p_e of IGBTs 61p, 62p, and 63p. The emitter wiring 85e and 85f is provided to acquire a common emitter potential when IGBTs 61p, 62p, and 63p connected in parallel are driven.

As shown in FIG. 11B, emitter wiring 85e connecting emitter terminal 61p_e of IGBT 61p to emitter terminal 62p_e of IGBT 62p has a parasitic resistor 80e and a parasitic inductance 90e. Emitter wiring 85f connecting emitter terminal 62p_e of IGBT 62p to emitter terminal 63p_e of IGBT 63p has a parasitic resistor 80f and a parasitic inductance 90f. Since the parasitic impedance (80e, 90c, 80f, 90f) of emitter wiring 85e and 85f is higher than the parasitic impedance (80c, 90c, 80d, 90d) of main circuit wiring 85c and 85d for collector current to flow, no collector current flows through emitter wiring 85e and 85f connecting the emitter terminals of the IGBTs.

When a steep current such as a short-circuit current flows through main circuit 102b, an induced voltage is generated by the parasitic inductance of the current path and a voltage drop is caused by the parasitic resistor of the current path. In other words, the voltage is held by the parasitic impedance of the current path.

Emitter wiring 85e and 85f connecting the emitter terminals is connected in parallel with main circuit wiring 85c and 85d on the negative side. Therefore, a voltage of the same magnitude as the voltage held by the parasitic impedance (80c, 90c, 80d, 90d) of main circuit wiring 85c and 85d on the negative side is held by the parasitic impedance (80e, 90e, 80f, 90f) of emitter wiring 85e and 85f.

Specifically, the current flowing from collector terminal 61p_c of IGBT 61p to negative node N1 will be described. The path of this current includes a path through main circuit wiring 85c having parasitic resistor 80c and parasitic inductance 90c and a path through emitter wiring 85e having parasitic resistor 80e and parasitic inductance 90e. These current paths are current paths parallel to each other. Since the voltages held by the parallel current paths are the same, the sum of voltages held by parasitic resistor 80c and parasitic inductance 90c which are parasitic impedance of main circuit wiring 85c on the negative side is equal to the sum of voltages held by parasitic resistor 80e and parasitic inductance 90e which are parasitic impedance of emitter wiring 85c.

In the above case, the voltage held by the parasitic impedance of main circuit wiring 85c on the negative side is the voltage between emitter terminal 61p_e of IGBT 61p and emitter terminal 62p_e of IGBT 62p. In other words, the emitter potential of IGBT 61p is higher than the emitter potential of IGBT 62p, so the gate-emitter voltages of two IGBTs 61p and 62p are different.

More generally, in main circuit 102b, since current flows from the respective emitter terminals 61p_e, 62p_e, and 63p_e of IGBTs 61p, 62p, and 63p toward negative node N2, the emitter potential of IGBT 61p and the emitter potential of IGBT 63p are higher than the emitter potential of IGBT 62p. In this case, comparing the gate-emitter voltages applied to the three IGBTs, the gate-emitter voltage applied to IGBT 62p is the highest, so the on-resistance is smallest in IGBT 62p because the highest current flows through IGBT 62p.

In this way, emitter wiring 85e and 85f connecting the emitter terminals of IGBTs 61p, 62p, and 63p connected in parallel has a difference in voltage held by the parasitic impedance of main circuit wiring 85c and 85d on the negative side. If a steep current such as a short-circuit current flows through main circuit 102b, this difference in voltage becomes large, and consequently, the gate-emitter voltages applied to IGBTs 61p, 62p, and 63p connected in parallel vary, and the on-resistances also vary accordingly.

In summary, the current balance when the current flowing into main circuit 102b is split to each of IGBTs 61p, 62p, and 63p connected in parallel is affected by the difference in wiring impedance for each split path and the variations in on-resistance of the IGBTs due to the difference in gate-emitter voltage. A voltage drop in an IGBT is the product of current flowing through the IGBT and the on-resistance. Therefore, the IGBT with the largest current flowing and the IGBT with the highest voltage drop among a plurality of IGBTs connected in parallel are not always the same.

### [Difference in How Short-Circuit Current Flows Depending on Conditions of Occurrence of Short-Circuit Fault]

Based on the above, how the path with the highest short-circuit current changes due to the difference in path impedance and how the power semiconductor element with the lowest on-resistance changes due to the difference in gate-emitter voltage, depending on the conditions of occurrence of arm short circuit and load short circuit, will be explained.

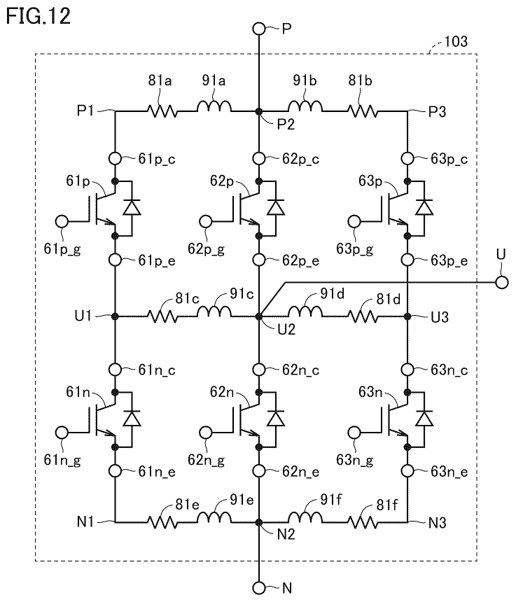

FIG. 12 is a diagram showing a configuration example of a main circuit for one phase of a power conversion device. Referring to FIG. 12, the upper arm of a main circuit 103 is constituted with three IGBTs 61p, 62p, and 63p connected in parallel, and the lower arm of main circuit 103 is constituted with three IGBTs 61n, 62n, and 63n connected in parallel.

IGBT 61p and IGBT 61n are connected in series between a positive node P1 and a negative node N1 via a connection node U1. IGBT 62p and IGBT 62n are connected in series between a positive node P2 and a negative node N2 via a connection node U2. IGBT 63p and IGBT 63n are connected in series between a positive node P3 and a negative node N3 via a connection node U3. Positive node P2 is connected to each of positive nodes P1 and P3 and further connected to positive terminal P. Negative node N2 is connected to each of negative nodes N1 and N3 and further connected to negative terminal N. Connection node U2 is connected to each of connection nodes U1 and U3 and further connected to a U-phase load terminal U.

Therefore, the collector terminal of each of IGBTs 61p, 62p, and 63p that constitute the upper arm is connected to positive terminal P via positive node P2. The emitter terminal of each of IGBTs 61n, 62n, and 63n that constitute the lower arm is connected to negative terminal N via negative node N2. The emitter terminals of IGBTs 61p, 62p, and 63p that constitute the upper arm and the collector terminals of IGBTs 61n, 62n, and 63n that constitute the lower arm are connected via connection nodes U1, U2, and U3.

As shown in FIG. 12, the wiring connecting positive node P1 to positive node P2 has a parasitic resistor 81a and a parasitic inductance 91a. The wiring connecting positive node P2 to positive node P3 has a parasitic resistor 81b and a parasitic inductance 91b. The wiring connecting connection node U1 to connection node U2 has a parasitic resistor 81c and a parasitic inductance 91c. The wiring connecting connection node U2 to connection node U3 has a parasitic resistor 81d and a parasitic inductance 91d. The wiring connecting negative node N1 to negative node N2 has a parasitic resistor 81e and a parasitic inductance 91e. The wiring connecting negative node N2 to negative node N3 has a parasitic resistor 81f and a parasitic inductance 91f. For simplicity in the following description, it is assumed that all parasitic resistors 81a to 81f have the same resistance and all parasitic inductances 91a to 91f have the same inductance.

In the following, each of the conditions of occurrence of arm short circuit and load short circuit will be described. First, a case where an arm short circuit is caused by an ON command being input to the IGBTs in the upper arm while IGBT 61n which is one of the IGBT's in the lower arm is in a conducting state due to a short circuit fault or a false ON signal input will be described. In this case, there are three paths for the short-circuit current to flow, namely, a path through IGBT 61p and IGBT 61n, a path through IGBT 62p and IGBT 61n, and a path through IGBT 63p and IGBT 61n. In other words, the short-circuit current flowing from positive terminal P to negative terminal N is split at positive node P2 of the upper arm and flows through all IGBTs 61p, 62p, and 63p in the upper arm and to IGBT 61n. In this case, the path through which the short-circuit current is most likely to flow is the path through IGBT 61p with the lowest wiring impedance. The element with the lowest on-resistance is IGBT 61p having the highest gate-emitter voltage.

Next, a case where an arm short circuit is caused by an ON command being input to the IGBTs in the upper arm while IGBT 62n is in a conducting state due to a short circuit fault or a false ON signal input will be described. In this case, there are three paths for the short-circuit current to flow, namely, a path through IGBT 61p and IGBT 62n, a path through IGBT 62p and IGBT 62n, and a path through IGBT 63p and IGBT 62n. In other words, the short-circuit current flowing from positive terminal P to negative terminal N is split at positive node P2 of the upper arm and flows through all IGBTs 61p, 62p, and 63p in the upper arm and to IGBT 62n. In this case, the path through which the short-circuit current is most likely to flow is the path through IGBT 62p with the lowest wiring impedance. The element with the lowest on-resistance is IGBT 62p having the highest gate-emitter voltage.

Next, a case where an arm short circuit is caused by an ON command being input to the IGBTs in the upper arm while IGBT 63n is in a conducting state due to a short circuit fault or a false ON signal input will be described. In this case, there are three paths for the short-circuit current to flow, namely, a path through IGBT 61p and IGBT 63n, a path through IGBT 62p and IGBT 63n, and a path through IGBT 63p and IGBT 63n. In other words, the short-circuit current flowing from positive terminal P to negative terminal N is split at positive node P2 of the upper arm and flows through all IGBTs 61p, 62p, and 63p in the upper arm and to IGBT 63n. In this case, the path through which the short-circuit current is most likely to flow is the path through IGBT 63p with the lowest wiring impedance. The element with the lowest on-resistance is IGBT 63p having the highest gate-emitter voltage.

Next, a case where a load short circuit occurs when IGBTs 61p, 62p, and 63p in the upper arm are on. In this case, the short-circuit current flows from positive terminal P to U-phase load terminal U. In other words, the short-circuit current is split at positive node P2 of the upper arm and flows through all IGBTs in the upper arm. In this case, the path through which the short-circuit current is most likely to flow is the path through IGBT 62p with the lowest wiring impedance. The element with the lowest on-resistance is IGBT 62p having the highest gate-emitter voltage.

Next, a case where an arm short circuit is caused by an ON command being input to the IGBTs in the lower arm while IGBT 61p which is one of the IGBTs in the upper arm is in a conducting state due to a short circuit fault or a false ON signal input will be described. In this case, there are three paths for the short-circuit current to flow, namely, a path through IGBT 61p and IGBT 61n, a path through IGBT 61p and IGBT 62n, and a path through IGBT 61p and IGBT 63n. In other words, the short-circuit current flowing from positive terminal P to negative terminal N flows through IGBT 61p and is split at connection node U1 and flows through all IGBTs 61n, 62n, and 63n in the lower arm. In this case, the path through which the short-circuit current is most likely to flow is the path through IGBT 62n with the lowest wiring impedance. The element with the lowest on-resistance is 62n having the highest gate-emitter voltage.

Next, a case where an arm short circuit is caused by an ON command being input to the IGBTs in the lower arm while IGBT 62p is in a conducting state due to a short circuit fault or a false ON signal input will be described. In this case, there are three paths for the short-circuit current to flow, namely, a path through IGBT 62p and IGBT 63n, a path through IGBT 62p and IGBT 62n, and a path through IGBT 62p and IGBT 63n. In other words, the short-circuit current flowing from positive terminal P to negative terminal N flows through IGBT 62p and is split at connection node U2 and flows through all IGBTs 61n, 62n, and 63n in the lower arm. In this case, the path through which the short-circuit current is most likely to flow is the path through IGBT 62n with the lowest wiring impedance. The element with the lowest on-resistance is IGBT 62n having the highest gate-emitter voltage.

Next, a case where an arm short circuit is caused by an ON command being input to the IGBTs in the lower arm while IGBT 63p is in a conducting state due to a short circuit fault or a false ON signal input will be described. In this case, there are three paths for the short-circuit current to flow, namely, a path through IGBT 63p and IGBT 63n, a path through IGBT 63p and IGBT 62n, and a path through IGBT 63p and IGBT 63n. In other words, the short-circuit current flowing from positive terminal P to negative terminal N flows through IGBT 63p and is split at connection node U3 and flows through all IGBTs 61n, 62n, and 63n in the lower arm. In this case, the path through which the short-circuit current is most likely to flow is the path through IGBT 63n with the lowest wiring impedance. The element with the lowest on-resistance is 62n having the highest gate-emitter voltage.

Next, a case where a load short circuit occurs when IGBTs 61n, 62n, and 63n in the lower arm are on. In this case, the short-circuit current flows from U-phase load terminal U to negative terminal N. In other words, the short-circuit current is split at connection node U2 on the positive side of the lower arm and flows through all IGBTs in the lower arm. In this case, the path through which the short-circuit current is most likely to flow is the path through IGBT 62n with the lowest wiring impedance, and the element with the lowest on-resistance is IGBT 62n having the highest gate-emitter voltage.

As described above, among a plurality of power semiconductor elements connected in parallel, which power semiconductor element has high current and voltage depends on the conditions of occurrence of arm short circuit and load short circuit. Therefore, it is not possible to determine the optimal power semiconductor element for abnormality detection in advance.

### [Difference in Current and Voltage due to Arrangement of Power Semiconductor Elements]

As described above, the degree of variations of current and voltage of a plurality of power semiconductor elements connected in parallel differs depending on the conditions of occurrence of short circuit fault. However, the difference in current and voltage of each of two power semiconductor elements arranged adjacent to each other is lower than when they are arranged at a distance from each other. This will be described below with reference to the drawings.

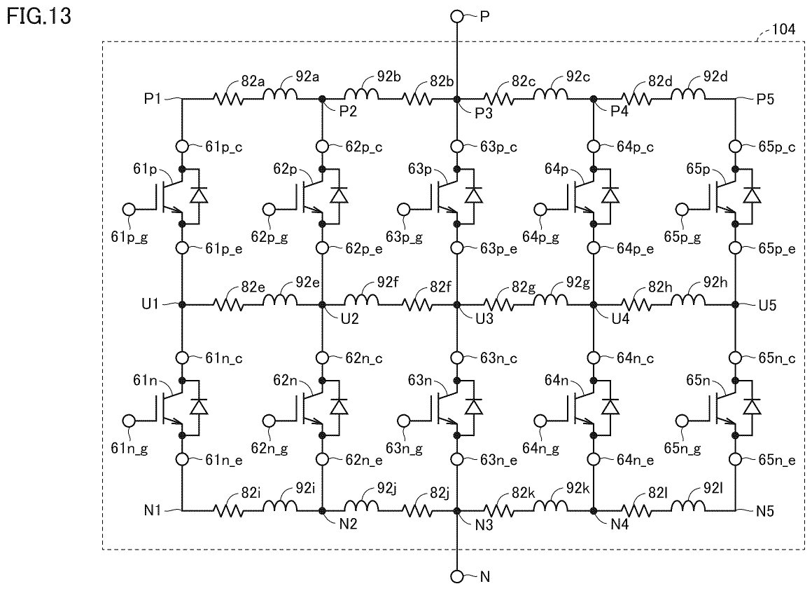

FIG. 13 is a diagram showing another configuration example of a main circuit for one phase of a power conversion device. Referring to FIG. 13, the upper arm of a main circuit 104 is constituted with five IGBTs 61p to 65p connected in parallel, and the lower arm of main circuit 104 is constituted with five IGBTs 61n to 65n connected in parallel. IGBT's 61p to 65p are arranged in a row on the main circuit board, and IGBTs 61n to 65n are arranged in a row on the same board in parallel with the direction of the arrangement of IGBTs 61p to 65p.

IGBT 61p and IGBT 61n are connected in series between a positive node P1 and a negative node N1 via a connection node U1. IGBT 62p and IGBT 62n are connected in series between a positive node P2 and a negative node N2 via a connection node U2. IGBT 63p and IGBT 63n are connected in series between a positive node P3 and a negative node N3 via a connection node U3. IGBT 64p and IGBT 64n are connected in series between a positive node P4 and a negative node N4 via a connection node U4. IGBT 65p and IGBT 65n are connected in series between a positive node P5 and a negative node N5 via a connection node U5.

Positive node P3 is connected to each of positive nodes P2 and P4 and further connected to positive terminal P. Positive node P1 is connected to positive node P2, and positive node P5 is connected to positive node P4. Negative node N3 is connected to each of negative nodes N2 and N4 and further connected to negative terminal N. Negative node NI is connected to negative node N2, and negative node N5 is connected to negative node N4. Connection node U3 is connected to each of connection nodes U2 and U4 and further connected to U-phase load terminal U. Connection node U1 is connected to connection node U2, and connection node U5 is connected to connection node U4.

Therefore, the collector terminal of each of IGBTs 61p to 65p that constitute the upper arm is connected to positive terminal P via positive node P3, The emitter terminal of each of IGBTs 61n to 65n that constitute the lower arm is connected to negative terminal N via negative node N3. The emitter terminals of IGBTs 61p to 65p that constitute the upper arm and the collector terminals of IGBTs 61n to 65n that constitute the lower arm are connected via connection nodes U1 to U5, respectively.

As shown in FIG. 13, the wiring connecting positive nodes P1 and P2 has a parasitic resistor 82a and a parasitic inductance 92a. The wiring connecting positive nodes P2 and P3 has a parasitic resistor 82b and a parasitic inductance 92b. The wiring connecting positive nodes P3 and P4 has a parasitic resistor 82c and a parasitic inductance 92c. The wiring connecting positive nodes P4 and PS has a parasitic resistor 82d and a parasitic inductance 92d.

Further, the wiring connecting negative nodes N1 and N2 has a parasitic resistor 82i and a parasitic inductance 92i. The wiring connecting negative nodes N2 and N3 has a parasitic resistor 82j and a parasitic inductance 92j. The wiring connecting negative nodes N3 and N4 has a parasitic resistor 82k and a parasitic inductance 92k. The wiring connecting negative nodes N4 and N5 has a parasitic resistor 821 and a parasitic inductance 921.

Further, the wiring connecting connection nodes U1 and U2 has a parasitic resistor 82e and a parasitic inductance 92e. The wiring connecting connection nodes U2 and U3 has a parasitic resistor 82f and a parasitic inductance 92f. The wiring connecting connection nodes U3 and U4 has a parasitic resistor 82g and a parasitic inductance 92g. The wiring connecting connection nodes U4 and US has a parasitic resistor 82h and a parasitic inductance 92h.

For simplicity in the following description, it is assumed that all parasitic resistors 81a to 811 have the same resistance R and all parasitic inductances 91a to 911 have the same inductance L. Only the parasitic impedance of the wiring for connecting the IGBTs in parallel with each other is considered.

In the following, a case where an arm short circuit is caused by an ON command being input to IGBTs 61p to 65p that constitute the upper arm when IGBT 61n which is one of IGBTs 61n to 65n that constitute the lower arm is in a conducting state due to a short circuit fault or a false ON signal input will be described by way of example. In this case, the short-circuit current flowing from positive terminal P to negative terminal N is split at positive node P3 of the upper arm, passes through all IGBTs 61p to 65p that constitute the upper arm, and flows to IGBT 61n.

In the above case, the path impedances of IGBT 61p and IGBT 65p arranged at a distance from each other are compared. In addition, the path impedances of IGBT 61p and IGBT 62p arranged adjacent to each other are compared.

The wiring impedance of the path from positive terminal P through IGBT 61p to collector terminal 61n_c of IGBT 61n is 2R+2L, which is the sum of parasitic resistors 82a and 82b and parasitic inductances 92a and 92b.

The wiring impedance of the path from positive terminal P through IGBT 62p to collector terminal 61n_c of IGBT 61n is 2R+2L, which is the sum of parasitic resistors 82b and 82e and parasitic inductances 92b and 92e.

The wiring impedance of the path from positive terminal P through IGBT 65p to the collector terminal 61n_c of IGBT 61n is 6R+6L, which is the sum of parasitic resistors 82c, 82d, 82h, 82g, 82f, and 82e and parasitic inductances 92c, 92d, 92h, 92g, 92f, and 92e.

Based on the above, it can be understood that when IGBT 61n is in a conducting state due to a short circuit fault or a false ON signal input, the difference in path impedance between IGBT 61p and IGBT 65p at a distance from each other is higher than the difference in path impedance between IGBT 61p and IGBT 62p adjacent to each other.

### [Example of Appropriate Arrangement of Detection Circuit]

Based on the above discussion, when a plurality of power semiconductor elements are connected in parallel and the parasitic impedance of the wiring is not negligible, it is necessary to provide detection circuits in a plurality of power semiconductor elements because the acquired physical quantity differs depending on the difference in magnitude of short-circuit current for each path. Furthermore, it can be understood that it is desirable that the power semiconductor elements to which detection circuits are connected should be arranged in a distributed and symmetrical manner as much as possible. In the following, an appropriate connection example of detection circuits will be described with specific examples.

### Example 1: a Case Where an Odd Number of Detection Circuits are Provided for an Odd Number of Power Semiconductor Elements

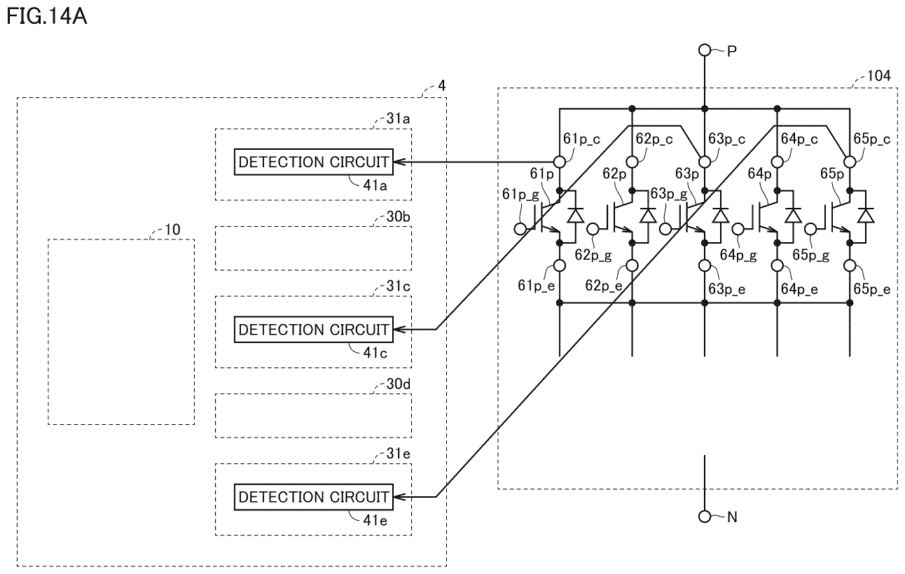

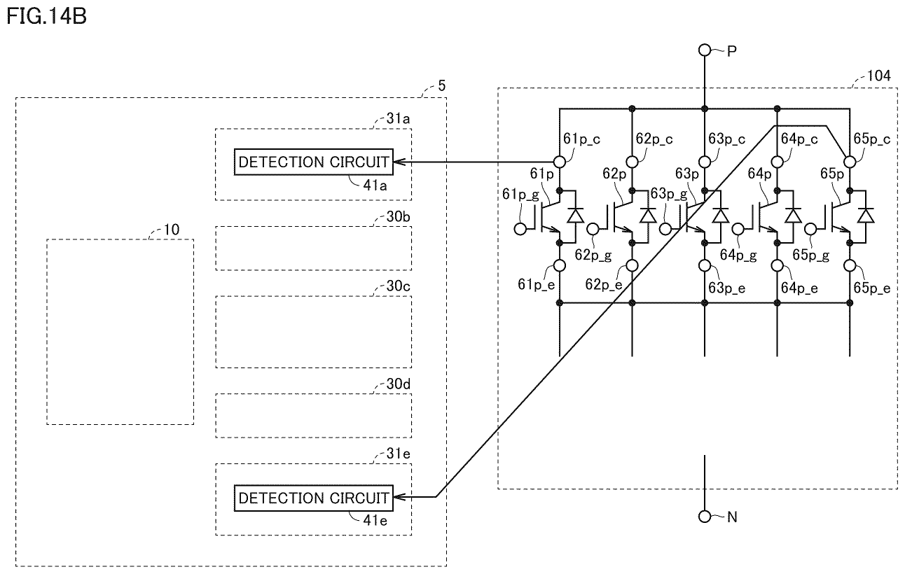

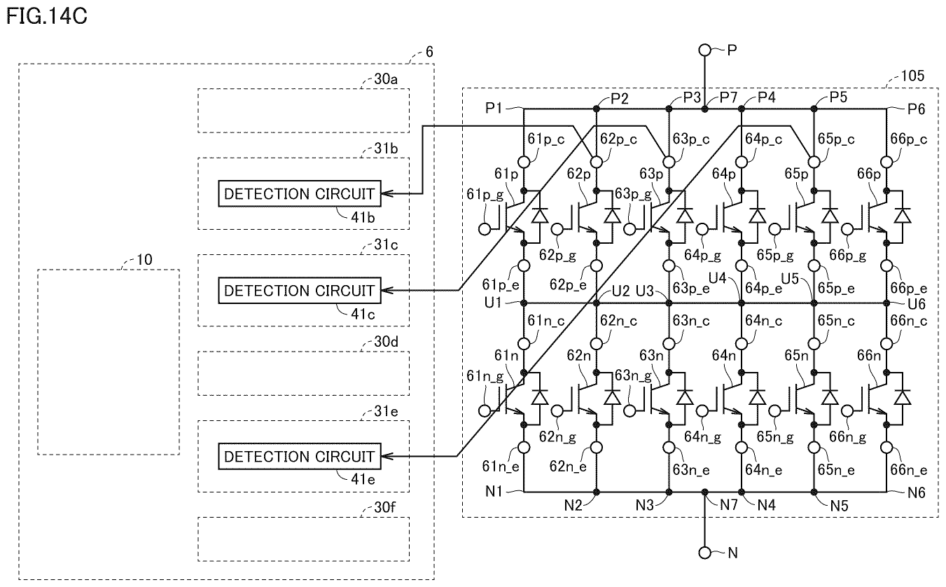

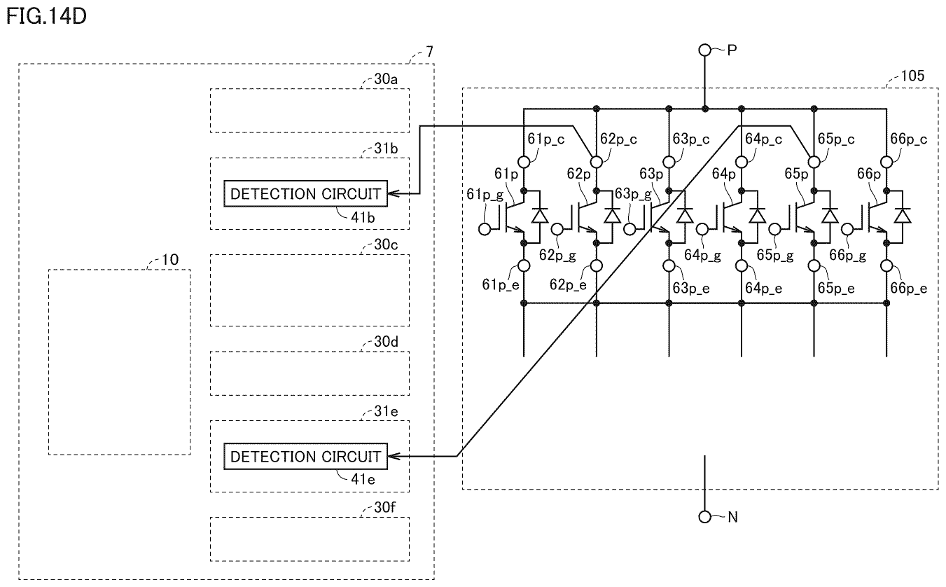

FIG. 14A is a diagram showing an example of a drive circuit that drives an upper arm of the main circuit shown in FIG. 13. As described with reference to FIG. 13, the upper arm of main circuit 104 has five IGBTs 61p to 65p connected in parallel, and these IGBTs are arranged in a row on the main circuit board. The lower arm of main circuit 104 is not shown in FIG. 14A.

As shown in FIG. 14A, a drive circuit 4 includes a common board 10 and individual boards 31a, 30b, 31c, 30d, and 31e corresponding to IGBTs 61p to 65p, respectively. Individual boards 31a, 31c, and 31e include detection circuits 41a, 41c, and 41e, respectively. Detection circuits 41a, 41c, and 41e detect an abnormality in main circuit 104 based on the collector-emitter voltages of the corresponding IGBTs 61p, 63p, and 65p, respectively.

In a case where a detection circuit is connected to each of three or more odd number of power semiconductor elements when an odd number of power semiconductor elements connected in parallel are arranged in a row as described above, an example of desirable connection is as follows. In other words, a detection circuit is provided for a power semiconductor element at the center in the order of arrangement, and a detection circuit is provided for some even number of power semiconductor elements that are symmetrical with respect to the above power semiconductor element at the center.

### Example 2: a Case Where an Even Number of Detection Circuits are Provided for an Odd Number of Power Semiconductor Elements

FIG. 14B is a diagram showing another example of the drive circuit that drives an upper arm of the main circuit shown in FIG. 13. As described with reference to FIG. 13, the upper arm of main circuit 104 has five IGBTs 61p to 65p connected in parallel, and these IGBTs are arranged in a row on the main circuit board. The lower arm of main circuit 104 is not shown in FIG. 14B.

As shown in FIG. 14B, a drive circuit 5 includes a common board 10 and individual boards 31a, 30b to 30d, and 31e corresponding to IGBTs 61p to 65p, respectively. Individual boards 31a and 31e include detection circuits 41a and 41e, respectively. Detection circuits 41a and 41e detect an abnormality in main circuit 104 based on the collector-emitter voltages of the corresponding IGBTs 61p and 65p, respectively.

In a case where a detection circuit is connected to each of an even number of power semiconductor elements when an odd number of power semiconductor elements connected in parallel are arranged in a row as described above, an example of desirable connection is as follows. In other words, a detection circuit is provided for some even number of power semiconductor elements that are symmetrical with respect to the power semiconductor element at the center in the order of arrangement.

### Example 3: a Case Where an Odd Number of Detection Circuits are Provided for an Even Number of Power Semiconductor Elements

FIG. 14C is a diagram showing an example of the drive circuit that drives an upper arm of the main circuit in another configuration example. A main circuit 105 in FIG. 14C is a main circuit for one phase of a power conversion device. The upper arm of main circuit 105 is constituted with six IGBTs 61p to 66p connected in parallel, and the lower arm of main circuit 105 is constituted with six IGBTs 61n to 66n connected in parallel. IGBTs 61p to 66p are arranged in a row on the main circuit board, and IGBTs 61n to 66n are arranged in a row on the same board in parallel with the direction of the arrangement of IGBTs 61p to 66p.

IGBT 61p and IGBT 61n are connected in series between a positive node P1 and a negative node N1 via a connection node U1. IGBT 62p and IGBT 62n are connected in series between a positive node P2 and a negative node N2 via a connection node U2. IGBT 63p and IGBT 63n are connected in series between a positive node P3 and a negative node N3 via a connection node U3. IGBT 64p and IGBT 64n are connected in series between a positive node P4 and a negative node N4 via a connection node U4. IGBT 65p and IGBT 65n are connected in series between a positive node P5 and a negative node N5 via a connection node US. IGBT 66p and IGBT 66n are connected in series between a positive node P6 and a negative node N6 via a connection node U6.

Positive node P2 is connected to each of positive nodes P1 and P3, and positive node P3 is connected to positive terminal P via positive node P7. Positive node P5 is connected to each of positive nodes P4 and P6, and positive node P4 is connected to positive terminal P via positive node P7. Negative node N2 is connected to each of negative nodes N1 and N3, and negative node N3 is connected to negative terminal N via negative node N7. Negative node N5 is connected to each of negative nodes N4 and N6, and negative node N4 is connected to negative terminal N via negative node N7. Connection node U2 is connected to each of connection nodes U1 and U3, and connection node U3 is connected to connection node U4. Connection node U5 is connected to each of connection nodes U4 and U6.

Therefore, the collector terminal of each of IGBTs 61p to 66p that constitute the upper arm is connected to positive terminal P via positive node P7. The emitter terminal of each of IGBTs 61n to 66n that constitute the lower arm is connected to negative terminal N via negative node N7. The emitter terminals of IGBTs 61p to 66p that constitute the upper arm and the collector terminals of IGBTs 61n to 66n that constitute the lower arm are connected via connection nodes U1 to U6, respectively.

As shown in FIG. 14C, a drive circuit 6 includes a common board 10 and individual boards 30a, 31b, 31c, 30d, 31e, and 30f corresponding to IGBTs 61p to 66p, respectively. Individual boards 31b, 31c, and 31e include detection circuits 41b, 41c, and 41e, respectively. Detection circuits 41b, 41c, and 41e detect an abnormality in main circuit 105 based on the collector-emitter voltages of the corresponding IGBTs 62p, 63p, and 65p, respectively.

In a case where a detection circuit is connected to each of an odd number of power semiconductor elements when an even number of power semiconductor elements connected in parallel are arranged in a row as described above, an example of desirable connection is as follows. In other words, when an odd number of detection circuits are provided for an even number of power semiconductor elements, the power semiconductor elements are divided into an odd number of blocks in the order of arrangement and a detection circuit is provided for one power semiconductor element in each block. In this case, it is appropriate to divide the power semiconductor elements into two blocks, namely, a block including N power semiconductor elements and a block including (N+1) power semiconductor elements, where N is a positive integer. When there are an odd number of power semiconductor elements in a block, as explained in Example 1, a detection circuit is provided for the power semiconductor element at the center in the order of arrangement. On the other hand, when there are an even number of power semiconductor elements in a block, a detection circuit is provided for one of two power semiconductor elements at the center in the order of arrangement.

### Example 4; a Case Where an Even Number of Detection Circuits are Provided for an Even Number of Power Semiconductor Elements

FIG. 14D is a diagram showing another example of the drive circuit that drives an upper arm of the main circuit shown in FIG. 14C. As described with reference to FIG. 14C, the upper arm of main circuit 105 has six IGBTs 61p to 66p connected in parallel, and these IGBTs are arranged in a row on the main circuit board. The lower arm of main circuit 105 is not shown in FIG. 14D.

As shown in FIG. 14D, a drive circuit 7 includes a common board 10 and individual boards 30a, 31b, 30c, 30d, 31e, and 30f corresponding to IGBTs 61p to 66p, respectively. Individual boards 31b and 31e include detection circuits 41b and 41e, respectively. Detection circuits 41b and 41e detect an abnormality in main circuit 105 based on the collector-emitter voltages of the corresponding IGBTs 62p and 65p, respectively.

In a case where a detection circuit is connected to each of an even number of power semiconductor elements when an even number of power semiconductor elements connected in parallel are arranged in a row as described above, an example of desirable connection is as follows. In other words, when an even number of detection circuits are provided for an even number of power semiconductor elements, the power semiconductor elements are divided into an even number of blocks in the order of arrangement and a detection circuit is provided for one power semiconductor element in each block. In this case, it is appropriate that all the blocks include an equal number of power semiconductor elements or that the power semiconductor elements are divided into two blocks, namely, a block including N power semiconductor elements and a block including (N+1) power semiconductor elements, where N is a positive integer. When there are an odd number of power semiconductor elements in a block, as explained in Example 1, a detection circuit is provided for the power semiconductor element at the center in the order of arrangement. On the other hand, when there are an even number of power semiconductor elements in a block, a detection circuit is provided for one of two power semiconductor elements at the center in the order of arrangement.

### Summary

In summary, a plurality of power semiconductor elements connected in parallel are arranged in a row or multiple rows on one or more main circuit boards. The detection circuit is provided for one power semiconductor element or each of some power semiconductor elements, among a plurality of power semiconductor elements in each row. Specifically, a case where any first row having K power semiconductor elements includes L (L is an integer of 1 or more and less than K) power semiconductor elements, each of which is associated with a detection circuit, will be described. In this case, if the quotient of K divided by L is N and the remainder is M (M is an integer of 0 or more and less than L), then K=L×N+M=N×(L−M)+(N+1)×M. Therefore, in order to divide this first row as evenly as possible into L blocks in the order of arrangement of power semiconductor elements, the first row is divided into L blocks all of which have N power semiconductor elements (when M=0), or the first row is divided into L blocks that have N or N+1 power semiconductor elements (when M>0). Then, if the number of power semiconductor elements in a block is an odd number, a detection circuit is provided for the power semiconductor element at the center, and if it is an even number, a detection circuit is provided for one of two power semiconductor elements at the center. As a result, the power semiconductor elements to which detection circuits are connected can be arranged in a distributed and symmetrical manner as much as possible. When a plurality of power semiconductor elements connected in parallel are arranged in multiple rows, symmetry can be increased if each row is associated with the same number of L detection circuits.

This configuration can reduce the difference between the wiring impedance of the current path through the power semiconductor element driven by individual board 31 having detection circuit 41 and the wiring impedance of the current path through the power semiconductor element driven by individual board 30 having no detection circuit 41. As a result, an abnormality in the main circuit can be detected with higher accuracy,

### Fifth Embodiment

In a drive circuit according to a fifth embodiment, a case where detection circuits 41 to 43 described in the first to third embodiments are used in combination will be described.

Detection circuits 41 to 43 differ in detection speed, detection accuracy, cost to configure the detection circuit, and circuit scale, depending on their type. Furthermore, the appropriate abnormality detection method differs depending on the connection method and driving conditions of a plurality of power semiconductor elements. For these reasons, when a plurality of individual boards 31 having abnormality detection means are used, an abnormality in the main circuit may be detected more effectively using different types of abnormality detection methods compared to using a single abnormality detection method. Description will be given in detail below with reference to the drawings.

### [Drive Circuit Example]

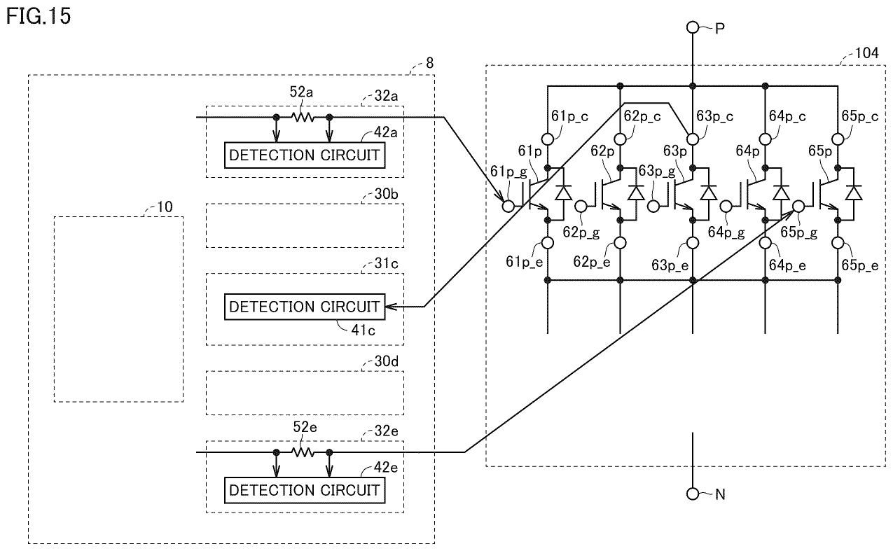

FIG. 15 is a diagram showing a configuration example of a drive circuit according to the fifth embodiment. FIG. 15 shows a configuration example of a drive circuit 8 that drives IGBTs 61p to 65p in the upper arm of main circuit 104 shown in FIG. 13. The lower arm of main circuit 104 is not shown in FIG. 15.

As shown in FIG. 15, drive circuit 8 includes a common board 10 and individual boards 32a, 30b, 31c, 30d, and 32e corresponding to IGBTs 61p to 65p, respectively.

Individual boards 32a and 32e include detection circuits 42a and 42e, respectively, having the configuration described in the second embodiment. Detection circuits 42a and 42e detect an abnormality in main circuit 104 based on the gate charge characteristic of the corresponding IGBTs 61p and 65p, respectively. Individual board 31c includes a detection circuit 41c having the configuration described in the first embodiment. Detection circuit 41c detects an abnormality in main circuit 104 based on the collector-emitter voltage of the corresponding IGBT 63p.

In this way, drive circuit 8 includes detection circuits 42a and 42e using the abnormality detection method based on the gate charge characteristic, and detection circuit 41c using the abnormality detection method based on the collector-emitter voltage. The abnormality detection method based on the gate charge characteristic can detect an arm short circuit with high speed, but it is difficult to detect a load short circuit. On the other hand, the abnormality detection method based on the collector-emitter voltage can detect both arm short circuit and load short circuit, although high-speed detection is difficult.

Therefore, when drive circuit 8 as shown in FIG. 15 is configured using these two detection methods, it is advantageous in that both arm short circuit and load short circuit can be detected and arm short circuit can be detected with high speed.

A plurality of power semiconductor elements corresponding to detection circuits may be distributed and arranged in a symmetrical manner for each type of detection method, or a plurality of power semiconductor elements corresponding to detection circuits may be distributed and arranged in a symmetrical manner for a plurality of detection methods combined as a whole.

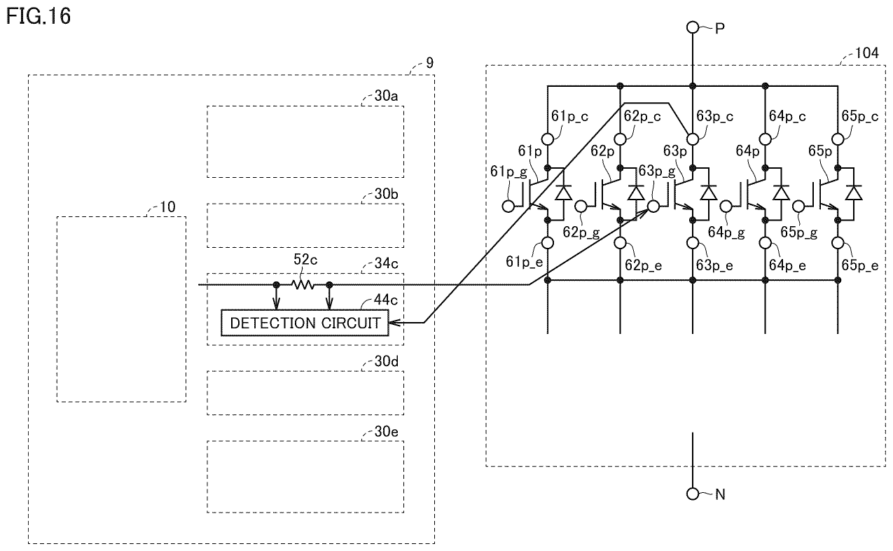

FIG. 16 is a diagram showing a configuration example of a drive circuit according to a modification of the fifth embodiment. FIG. 16 shows a configuration example of a drive circuit 9 that drives IGBTs 61p to 65p in the upper arm of main circuit 104 shown in FIG. 13. The lower arm of main circuit 104 is not shown in FIG. 16.

As shown in FIG. 16, drive circuit 9 includes a common board 10 and individual boards 30a, 30b, 34c, 30d, and 30e corresponding to IGBTs 61p to 65p, respectively. Individual board 34c has a detection circuit 44c with different types of abnormality detection means. Specifically, detection circuit 44c detects an abnormality based on the collector-emitter voltage of the corresponding IGBT 63p as described in the first embodiment, and also detects an abnormality based on the gate charge characteristic of the corresponding IGBT 63p as described in the second embodiment.

In this way, by using different types of detection methods, detection circuit 44c with excellent in detection accuracy and detection speed can be provided. Unlike the case of FIG. 16, the drive circuit may include a plurality of detection circuits with different types of detection methods,

### [Effects of Fifth Embodiment]

As described above, the drive circuit according to the fifth embodiment provides different types of detection methods. Therefore, it is possible to design a drive circuit capable of detecting an abnormality at low cost and effectively according to the application and usage environment of a plurality of power semiconductor elements connected in parallel with each other.

Embodiments disclosed here should be understood as being illustrative rather than being limitative in all respects. For example, the embodiments can be freely combined, and the configuration of each embodiment can be partially modified or omitted as appropriate. The scope of the subject application is shown not in the foregoing description but in the claims, and it is intended that all modifications that come within the meaning and range of equivalence to the claims are embraced here.

### REFERENCE SIGNS LIST

1 to 9 drive circuit, 10 common board, 11 switching circuit, 12 turn-on circuit, 13 turn-off circuit, 14 logical operation circuit, 15, 21a to 21c soft shutdown circuit, 16a, 16b NOT circuit, 17 AND circuit, 18 SRFF circuit, 19a, 19b switching element, 20a, 20b common gate resistor, 20c output node, 23 MOSFET, 24, 26 resistor element, 25 diode, 30 to 34 individual board, 41 to 44 detection circuit, 41A detection unit, 41B signal holding unit, 52 individual gate resistor, 61n to 66n, 61p to 66p IGBT (power semiconductor element), 101 to 105 main circuit, A1 drive signal output terminal, CS control signal, D1, D2c, D2a detection signal input terminal, DRC drive command, DRS drive signal, DTS detection signal (abnormality detection signal), F1 detection signal output terminal, GND ground, N negative terminal, N1 to N7 negative node, P positive terminal, P1 to P7 positive node, U1 to U6 connection node, S1 control signal input terminal, U U-phase load terminal, VDD power supply node.

1. A drive circuit for driving a plurality of power semiconductor elements connected in parallel with each other, the drive circuit comprising:
a common board to generate a common drive signal for controlling on and off of all of the power semiconductor elements connected in parallel; and
a plurality of individual boards, wherein
each of the individual boards is provided individually for a corresponding power semiconductor element among the power semiconductor elements, and supplies the drive signal to the corresponding power semiconductor element,
among the individual boards, one individual board or each of some individual boards includes a detection circuit, and
when detecting an abnormality in electrical characteristics of the corresponding power semiconductor element, the detection circuit changes the drive signal by transmitting an abnormality detection signal to the individual boards and the common board, or transmitting the abnormality detection signal to the common board without transmitting the abnormality detection signal to the individual boards.

2. The drive circuit according to claim 1, wherein
the power semiconductor elements are arranged in a row or multiple rows on one or more main circuit boards,
any first row having K power semiconductor elements includes L power semiconductor elements each associated with the detection circuit, where L is an integer of 1 or more and less than K,
when a quotient of K divided by L is N and a remainder is M, where M is an integer of 0 or more and less than L, the first row is divided into L blocks all of which have N power semiconductor elements, or L blocks that have N or N+1 power semiconductor elements, in order of arrangement of the power semiconductor elements, and
the detection circuit is provided for a power semiconductor element at center when a number of power semiconductor elements in the block is an odd number, and the detection circuit is provided for one of two power semiconductor elements at center when a number of power semiconductor elements in the block is an even number.

3. The drive circuit according to claim 2, wherein
the power semiconductor elements are arranged in multiple rows on one or more main circuit boards, and
each of the rows is associated with an equal number of L detection circuits.

4. The drive circuit according to claim 2, wherein when the detection circuit is provided for each of three or more odd number of power semiconductor elements in a row in which an odd number of power semiconductor elements are arranged, the detection circuit is provided for a power semiconductor element at center in order of arrangement, and the detection circuits are provided for some power semiconductor elements that are symmetrical with respect to the power semiconductor element at center.

5. The drive circuit according to claim 2, wherein when the detection circuit is provided for each of an even number of power semiconductor elements in a row in which an odd number of power semiconductor elements are arranged, the detection circuits are provided for some power semiconductor elements that are symmetrical with respect to a power semiconductor element at center in order of arrangement.

6. The drive circuit according to claim 2, wherein when the detection circuit is provided for each of three or more odd number of power semiconductor elements in a row in which an even number of power semiconductor elements are arranged, the detection circuit is provided for one of two power semiconductor elements at center in order of arrangement, and the detection circuits are provided for some power semiconductor elements that are symmetrical with respect to the two power semiconductor elements at center.

7. The drive circuit according to claim 2, wherein when the detection circuit is provided for each of an even number of power semiconductor elements in a row in which an even number of power semiconductor elements are arranged, the detection circuits are provided for some power semiconductor elements that are symmetrical with respect to two power semiconductor elements at center in order of arrangement.

8. The drive circuit according to claim 1, wherein when receiving the abnormality detection signal from the detection circuit, the common board changes a logic value of the drive signal to turn off the power semiconductor elements.

9. The drive circuit according to claim 1, wherein when receiving the abnormality detection signal from the detection circuit, each of the individual boards changes a potential of the drive signal by connecting a transmission path of the drive signal to a reference potential via a resistor element.

10. The drive circuit according to claim 1, wherein the detection circuit detects an abnormality in the corresponding power semiconductor element, based on a voltage between main terminals of the corresponding power semiconductor element.

11. The drive circuit according to claim 1, wherein the detection circuit detects an abnormality in the corresponding power semiconductor element, based on a gate charge characteristic of the corresponding power semiconductor element.

12. The drive circuit according to claim 1, wherein
the power semiconductor element corresponding to the detection circuit has a first main terminal, a second main terminal, and a sense terminal for splitting part of main current flowing from the first main terminal to the second main terminal, and the second main terminal and the sense terminal are connected by wiring, and
the detection circuit detects an abnormality in the corresponding power semiconductor element, based on a voltage between the second main terminal and the sense terminal.

13. The drive circuit according to claim 1, wherein
the drive circuit includes a first individual board and a second individual board as the individual board including the detection circuit, and
a method by which the detection circuit included in the first individual board detects an abnormality in the corresponding power semiconductor element is different from a method by which the detection circuit included in the second individual board detects an abnormality in the corresponding power semiconductor element.

14. The drive circuit according to claim 1, wherein the detection circuit detects an abnormality in the corresponding power semiconductor element using a plurality of different methods.
